(19) United States
(12) Patent Application Publication
(10) Pub. No.: US 2026/0354203 A1
(43) Pub. Date: Nov. 5, 2026

(54) ELECTRONIC DEVICES AND METHODS OF MANUFACTURING ELECTRONIC DEVICES

(71) Applicant: Amkor Technology Singapore Holding Pte. Ltd., Singapore (SG)

(72) Inventors: In Soo Choi, Seoul (KR); Sang Hyun Jin, Incheon (KR); Jun Ho Kang, Incheon (KR); Hee Taek Jung, Incheon (KR); Hyeon Sik Seo, Incheon (KR)

(73) Assignee: Amkor Technology Singapore Holding Pte. Ltd., Singapore (SG)

(21) Appl. No.: 19/663,244

(22) Filed: Apr. 29, 2026

Related U.S. Application Data
(60) Provisional application No. 63/799,286, filed on May 2, 2025.
(60) Provisional application No. 63/799,292, filed on May 2, 2025.

(51) Int. Cl. H10W 42/60; H10W 20/00; H10W 20/20

(52) U.S. Cl. CPC H10W 42/60; H10W 20/063; H10W 20/233

(57) ABSTRACT

In one example, an electronic device includes a first passivation structure comprising protrusions on an upper side of the first passivation structure. First traces can be embedded in the first passivation structure and recessed from the protrusions. Second traces are disposed on the protrusions, and a second passivation structure is disposed over the first passivation structure, the first traces, and the second traces. A first metallic barrier can be disposed between the first traces and the first passivation structure. A second metallic barrier is disposed between the second traces and the first passivation structure. A first inorganic barrier is disposed over an upper side of the first traces, on a sidewall of the protrusions, and between the second traces and the second passivation structure. Other examples and related methods are also disclosed herein.

### TECHNICAL FIELD

The present disclosure relates, in general, to electronic devices, and more particularly, to electronic devices and methods for manufacturing electronic devices.

### BACKGROUND

Prior electronic packages and methods for forming electronic packages are inadequate, resulting in, for example, excess cost, decreased reliability, relatively low performance, or package sizes that are too large. Further limitations and disadvantages of conventional and traditional approaches will become apparent to one of skill in the art, through comparison of such approaches with the present disclosure and reference to the drawings.

### BRIEF DESCRIPTION OF THE DRAWINGS

FIG. 1A illustrates a cross-sectional view of an example electronic device.

FIG. 1B illustrates a cross-sectional view of a detailed region of an example electronic device.

FIGS. 2A to 2T illustrate an example method for manufacturing an electronic device using cross-sectional views.

FIGS. 3A to 3E illustrate an example method for manufacturing an electronic device using cross-sectional views.

FIGS. 4A to 4C illustrate cross-sectional views of an example electronic device.

FIGS. 5A to 5L illustrate an example method for manufacturing an electronic device using cross-sectional views.

FIGS. 6A to 6H illustrate an example method for manufacturing an electronic device using cross-sectional views.

FIGS. 7A and 7B illustrate cross-sectional views of an example electronic device.

FIGS. 8A to 8L illustrate an example method for manufacturing an electronic device.

FIG. 9A to 9M illustrate an example method for manufacturing an electronic device.

FIGS. 10A to 10E illustrates an example method for manufacturing features of an electronic device.

The following discussion provides various examples of electronic devices and methods of manufacturing electronic devices. Such examples are non-limiting, and the scope of the appended claims should not be limited to the particular examples disclosed. In the following discussion, the terms “example” and “e.g.” are non-limiting.

The figures illustrate the general manner of construction, and descriptions and details of well-known features and techniques may be omitted to avoid unnecessarily obscuring the present disclosure. In addition, elements in the drawing figures are not necessarily drawn to scale. For example, the dimensions of some of the elements in the figures may be exaggerated relative to other elements to help improve understanding of the examples discussed in the present disclosure. The same reference numerals in different figures denote the same elements.

The term “or” means any one or more of the items in the list joined by “or”. As an example, “x or y” means any element of the three-element set {(x), (y), (x, y)}. As another example, “x, y, or z” means any element of the seven-element set {(x), (y), (z), (x, y), (x, z), (y, z), (x, y, z)}.

The terms “comprises,” “comprising,” “includes,” and “including” are “open ended” terms and specify the presence of stated features, but do not preclude the presence or addition of one or more other features.

The terms “first,” “second,” etc. may be used herein as labels to describe various elements, and these elements should not be limited by these terms. These terms are only used to distinguish one element from another. Thus, for example, a first element discussed in this disclosure could be termed a second element elsewhere without departing from the teachings of the present disclosure. Similarly, terms disclosed as singular can be plural in some embodiments, and elements disclosed as plural can be singular in some embodiments.

Unless specified otherwise, the term “coupled” may be used to describe two elements directly contacting each other or describe two elements indirectly coupled by one or more other elements. For example, if element A is coupled to element B, then element A can be directly contacting element B or indirectly coupled to element B by an intervening element C. Similarly, the terms “over” or “on” may be used to describe two elements directly contacting each other, describe two elements indirectly coupled by one or more other elements, or two elements overlapping vertically as depicted. Unless specified otherwise, the term “coupled” can refer to a mechanical coupling or an electrical coupling.

### DESCRIPTION

An example electronic device includes a first passivation structure, a first inorganic barrier over the first passivation structure, and a first metallic barrier disposed over the first inorganic barrier. A conductive structure can be disposed over the first metallic barrier. A second metallic barrier can be disposed over the conductive structure, and a second inorganic barrier disposed over the second metallic barrier.

In various examples, a lateral end of the second metal barrier terminates outside a footprint of the conductive structure by a distance of approximately 0.25 micrometers (μm) to approximately 1.5 μm. The first metallic barrier and the second metallic barrier can surround the conductive structure. The first inorganic barrier and the second inorganic barrier can surround the first metallic barrier and the second metallic barrier. The second inorganic barrier contacts lateral ends of the second metallic barrier outside a footprint of the conductive structure. The conductive structure comprises traces and the second inorganic barrier extending continuously between adjacent traces. The first metallic barrier comprises titanium and the second metallic barrier comprises nickel. A bottom side of the second metallic barrier contacts a top side of the first metallic barrier.

Another example electronic device can include a first passivation structure comprising a plurality of protrusions on an upper side of the first passivation structure. First traces can be embedded in the first passivation structure and recessed from the protrusions. Second traces are disposed on the protrusions, and a second passivation structure is disposed over the first passivation structure, the first traces, and the second traces. A first metallic barrier can be disposed between the first traces and the first passivation structure. A second metallic barrier is disposed between the second traces and the first passivation structure. A first inorganic barrier is disposed over an upper side of the first traces, on a sidewall of the protrusions, and between the second traces and the second passivation structure.

In various examples, the first metallic barrier comprises titanium and the first inorganic barrier comprises at least one of silicon nitride (Si3N4), silicon dioxide (SiO2), or silicon oxynitride (SiON). The electronic device can include a conductive via in the first passivation structure, and a second passivation structure over the first inorganic barrier and the conductive via. The second passivation structure contacts a sidewall of first passivation structure over the conductive via. The second passivation structure contacts a top side of the conductive via. The first inorganic barrier contacts a top side of the conductive via. Second traces are laterally interleaved with the first traces. The electronic device can include a second passivation structure over the first inorganic barrier, third traces disposed in the second passivation structure, a third metallic barrier between the third traces and the second passivation structure, and a second inorganic barrier over the third traces. The third traces are recessed from an upper side of the second passivation structure, and the third traces are vertically aligned with the first traces.

In still another example electronic device, a signal distribution structure includes a first passivation structure and a conductive structure. The conductive structure includes a conductive via extending through the first passivation structure, and a tip of the conductive via protrudes from the first passivation structure at a first side of the signal distribution structure. An electronic component can be coupled to a second side of signal distribution structure opposite the first side of the signal distribution structure. An external interconnect can be coupled to the tip of the conductive via.

In various examples, the conductive structure comprises a plurality of first traces embedded in the first passivation structure. The conductive structure can include first traces disposed over the first passivation structure. A second passivation structure can be disposed over the plurality of first traces and the first passivation structure.

Electronic devices and related methods can comprise conductive elements resistant to oxidation. In some examples, a conductive element such as a trace or pad can be surrounded by a barrier. For example, a titanium barrier layer can completely encircle a cross section of a copper conductive element, resulting in a 4-face or all-sided, metallic-barrier structure. In some examples, an inorganic material can completely encircle a cross section of a conductive element, resulting in a 4-face or all-sided non-metallic barrier. In some examples, a 4-face or all-sided barrier can comprise metallic portions and inorganic portions. For example, a lower side of a barrier can comprise titanium and an upper side of the barrier can comprise an inorganic material.

The barrier can comprise a two-piece or multiple-piece barrier structure. For example, a barrier layer can be formed, then a conductive element can be formed over the barrier layer with an exposed side, then a second barrier layer can be formed over the exposed side of the conductive element to surround the conductive element. In some examples, the barrier layers described herein can be applied to embedded traces (ETR) or to conductors made using a semi-additive process (SAP).

In some examples, a four-sided barrier (e.g., encircling a conductive element) can reduce oxidation compared to a three-sided barrier (e.g., with one side of the conductive element exposed from the barrier). Examples of four-sided barriers can also mitigate increased resistance over time that can result from oxidation of conductive elements. For example, four-sided barriers can limit increases in resistance of a conductive element over time compared to conductive elements without barriers. Reliability of electronic devices can thus be improved by using a four-sided barrier. Density can also be improved in hybrid devices including SAP and ETR trace elements.

Some examples can include vias with round shapes formed in a passivation structure, then revealed as a portion of the passivation structure is removed. The removal process can include a plasma etch, dry etch step, or laser debonding step to remove a barrier of glass or passivation. An O2 plasma removal step can be used to reveal rounded ends of vias. The resulting vias can have a round geometry protruding from passivation with reduced incidences of plating voids or sputtering voids.

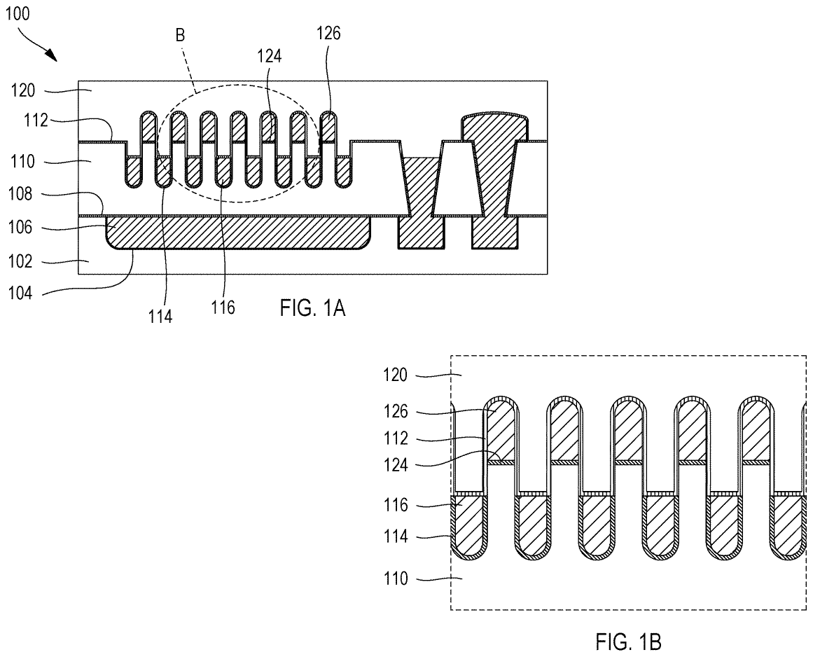

Referring now to FIG. 1A, a cross-sectional view of example signal distribution structure 100 for an electronic device is shown, in accordance with various examples. FIG. 1B shows details of region B in FIG. 1A. In the example shown in FIGS. 1A and 1B, signal distribution structure 100 comprises passivation structure 102, passivation structure 110, and passivation structure 120. Conductive structure 106 can be provided in patterns of passivation structure 102. Conductive structure 116 can be provided in patterns of passivation structure 110. Conductive structure 126 can be provided in conductive structure 126. For example, conductive structure 126 can be on passivation structure 110, with passivation structure 120 over conductive structure 126. Metallic barrier layers 104, 114, and 124 can be along the lower sides of conductive structures 106, 116, 126, respectively. Metal barrier layers can also be referred to herein as seeds, barriers, metallic barriers, or using other similar terms. Metal barrier 104 can be along the sidewalls and lower side of conductive structure 106. For example, metal barrier 104 can be between conductive structure 106 and passivation structure 102. Metal barrier 114 can be on the sidewalls and lower sides of conductive structure 116. For example, metal barrier 114 can be between conductive structure 116 and passivation structure 110. Metal barrier 124 can be on the lower side of conductive structure 126. For example, metal barrier 124 can be between conductive structure 126 can passivation structure 110. Inorganic barrier 108 can serve as a barrier around conductive structure 106. For example, inorganic barrier 108 can be between conductive structure 106 and passivation structure 110. Inorganic barrier 112 can serve as a barrier around conductive structures 116 and 126. For example, inorganic barrier 112 can be between conductive structure 116 and passivation structure 120, between conductive structure 126 and passivation structure 120.

In accordance with various examples, conductive structures 106, 116, and 126 can comprise pads, vias, traces, interconnects, under-bump metallization (UBM), pillars, posts, studs, or other conductive structures. In some examples, traces of conductive structure 106 provided in passivation structure 110 can comprise ETR. In some examples, traces of conductive structure 126 provided over protrusions of passivation structure 110 can be formed using an SAP.

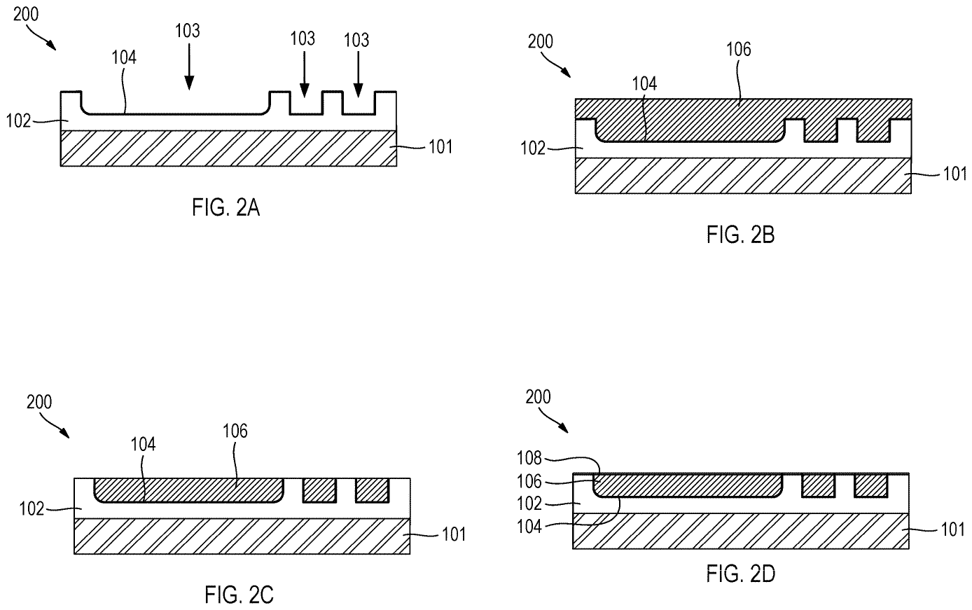

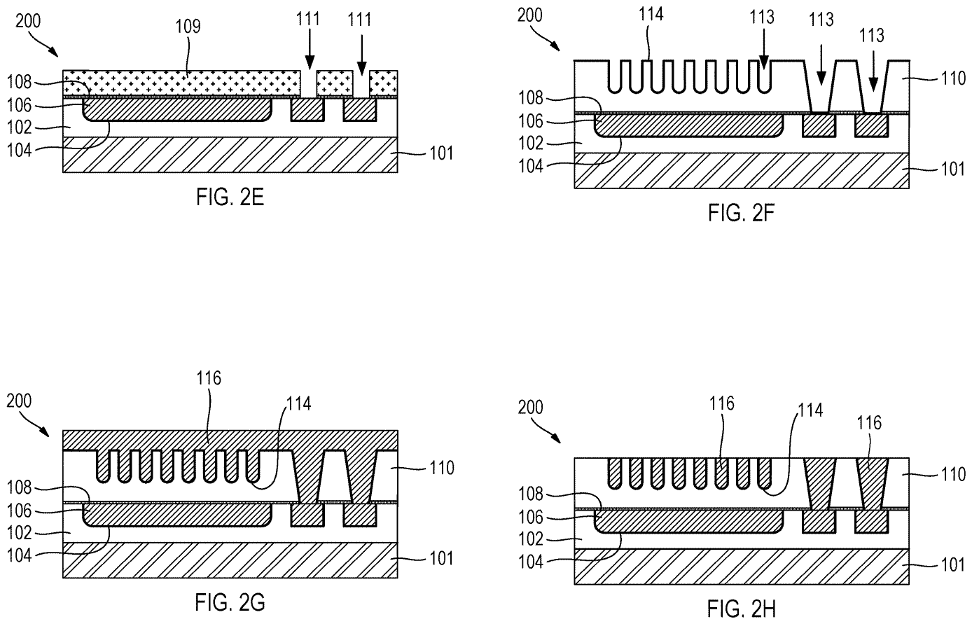

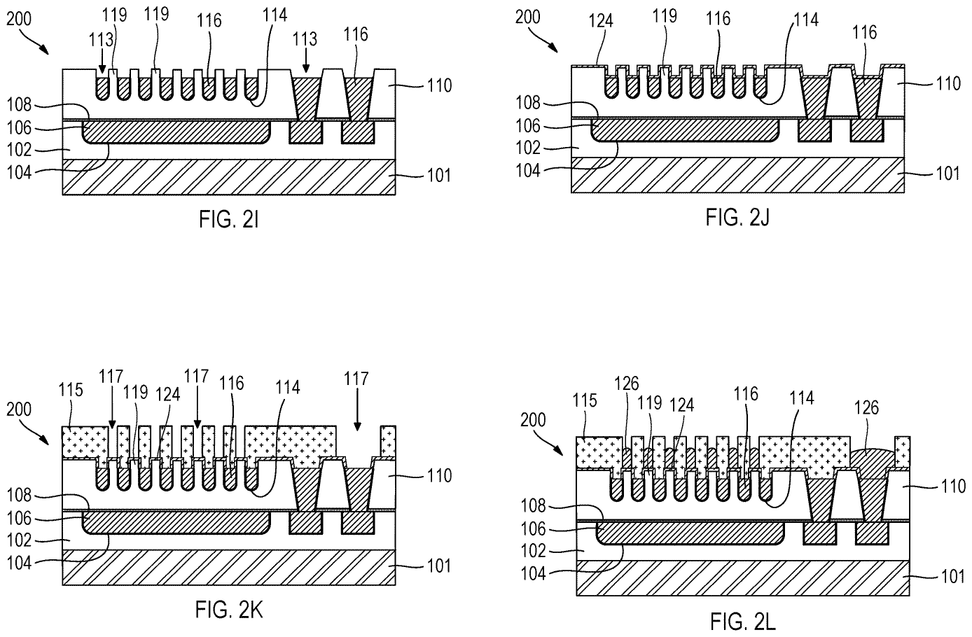

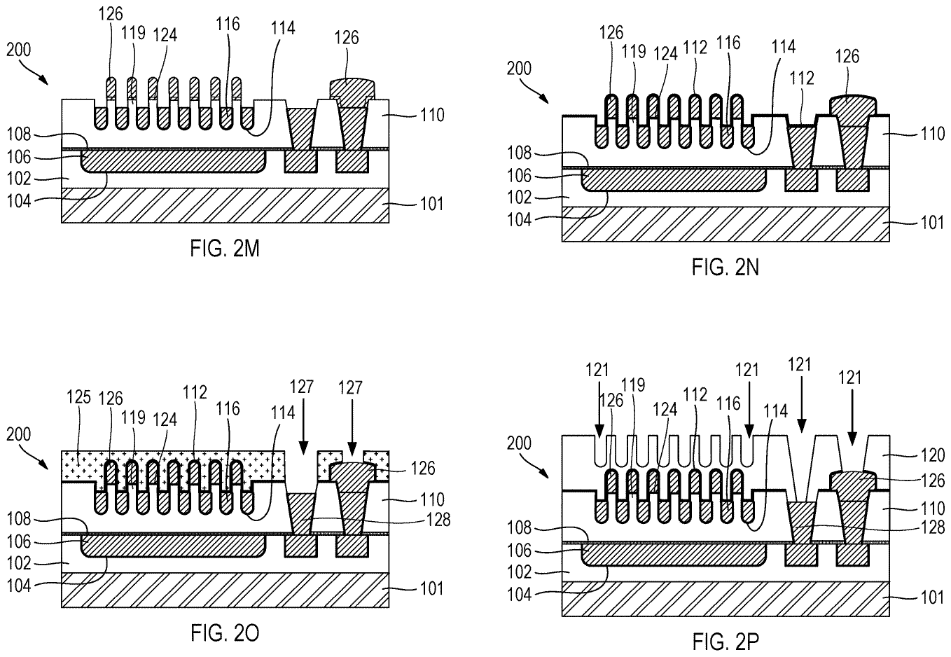

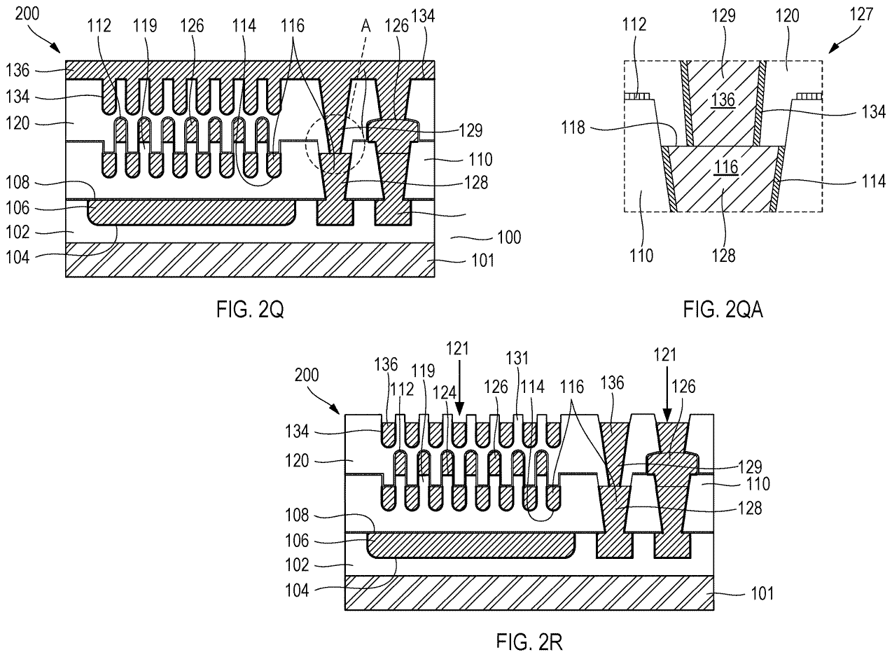

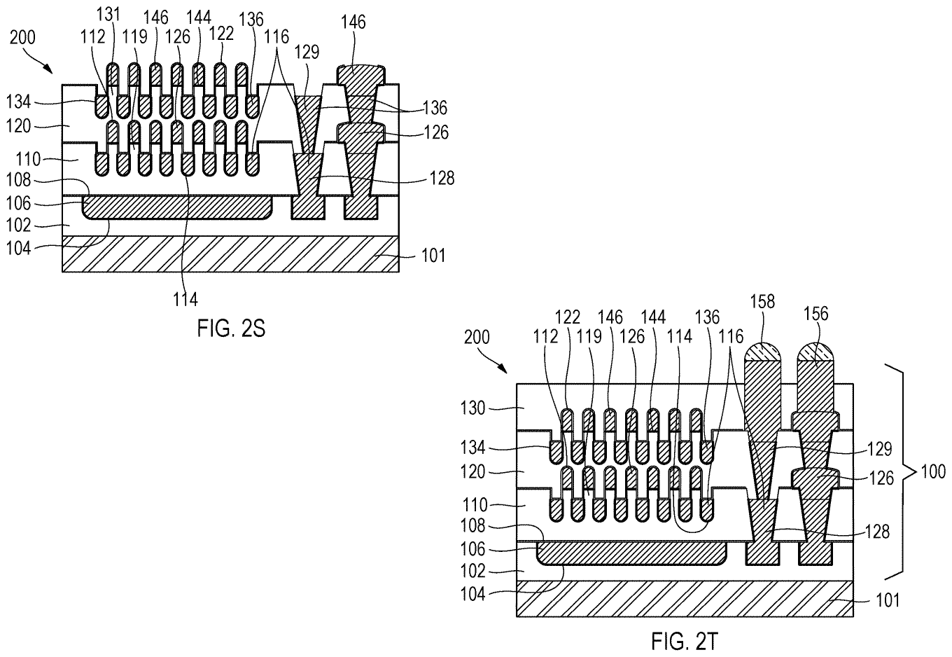

FIGS. 2A to 2T show an example method for manufacturing an electronic device 200, in accordance with various examples. Electronic device 200 can include signal distribution structure 100 of FIG. 1, in some examples.

FIG. 2A shows a cross-sectional view of electronic device 200 at an early stage of manufacture. In the example of FIG. 2A, passivation structure 102 can be provided over substrate 101.

In accordance with various examples, substrate 101 can comprise or be referred to as a wafer, a reconstituted wafer, a panel, a carrier, a temporary substrate, or a temporary carrier. For example, substrate 101 can be a semiconductor wafer including electronic components formed in rows and columns across the wafer and separated by saw streets. In some examples, substrate 101 can be a reconstituted wafer including known good electronic components arranged in rows and columns with encapsulant located between adjacent known good electronic components. In some examples, substrate 101 can be a panel including one or more semiconductor wafers and/or reconstituted wafers located thereon. In some examples, substrate 101 can be a temporary carrier on which signal distribution structure 100 is formed with substrate 101 being removed after coupling electronic components to signal distribution structure 100. The thickness of substrate 101 can range from about 50 micrometers (μm) to about 2000 μm. The terms about, approximately, or similar terms as used with numeric values can mean +/−5%, +/−10%, +/−15%, +/−20%, or +/−25%.

In accordance with various examples, passivation structure 102 can be provided to cover the upper side of substrate 101. Passivation 102 can be formed by physical vapor deposition (PVD), chemical vapor deposition (CVD), metal organic chemical vapor deposition (MOCVD), atomic layer deposition (ALD), low pressure chemical vapor deposition (LPCVD), plasma enhanced chemical vapor deposition (PECVD), spin coating, spray coating, dip coating, rod coating, or any other suitable deposition process. Passivation structure 102 can include one or more layers of dielectric material. For example, passivation structure 102 can include one or more layers of photo-definable organic dielectric materials such as, for example, polyimide (Pl), benzocyclobutene (BCB), or polybenzoxazole (PBO). Such dielectric materials can be spray coated, spin coated, or otherwise coated in liquid form, attached as a pre-formed film, or deposited in any other suitable manner for forming an electrically insulating material such as PI, BCB, PBO, or the like over substrate 101.

Passivation structure 102 can be patterned using, for example, a photo-patterning process that can include a photolithographic mask through which light is exposed to photo-pattern desired features, such as pattern 103, in passivation structure 102. Pattern 103 can be configured to form vias, traces, ground planes, or any other desired conductive structures in passivation structure 102.

In accordance with various examples, seed 104 can be provided over passivation structure 102. Seed 104 can be provided in patterns 103 formed on the upper side of passivation structure 102. Seed 104 can provide a metal seed layer for subsequent metal plating operations. In some examples, seed 104 can be a multi-layer structure. For example, seed 104 can include a barrier layer (e.g., Ti, TiN, or TiW) formed directly on the dielectric material of passivation structure 102 and a plating seed (e.g., Cu) formed on the barrier layer. In some examples, seed 104 is formed using PVD; however, barrier 104 can be formed via sputtering, electroless plating, CVD, MOCVD, ALD, LPCVD, PECVD, or any other suitable deposition process. The thickness of seed 104 can be between 0.1 μm and 1.0 μm, 0.15 μm and 0.5 μm, or about 0.3 μm. For example, the thickness of the barrier layer (e.g., Ti, TiN, TiW layer) can be between 15 nanometers (nm) and 100 nm or between 30 nm and 50 nm, and the thickness of the plating seed (e.g., Cu layer) can be between 50 nm and 500 nm, or between 100 nm and 300 nm. Seeds can be referred to herein as barriers, metallic barriers, barrier layers, or similar when arranged to protect a conductive structure.

FIG. 2B shows a cross-sectional view of electronic device 200 at a later stage of manufacture. In the example of FIG. 2B, conductive structure 106 can be provided over seed 104 and passivation structure 102.

Conductive structure 106 can be provided by electroless plating, electrolytic plating, sputtering, PVD, CVD, MOCVD, ALD, LPCVD, PECVD, or any other suitable deposition process. Conductive structure 106 can comprise metal(s) such as Cu, Al, Ti, TiW, Au, Ag, Ni, alloys, compounds, or other suitable electrically conductive materials. Conductive structure 106 can be provided on seed 104. In accordance with various examples, seed 104 can act as a seed for plating conductive structure 106. Conductive structure 106 can be provided to completely cover the upper side of seed 104 and passivation structure 102.

FIG. 2C shows a cross-sectional view of electronic device 200 at a later stage of manufacture. In the example shown in FIG. 2C, a chemical mechanical planarization (CMP) can be used to remove portions of seed 104 and of conductive structure 106 from the regions over the upper-most side of passivation structure 102, leaving conductive structure 106 and seed 104 within patterns 103. The remaining electrically conductive material of conductive structure 106 and seed 104 can fill or partially fill pattern 103 to provide traces, vias, pads, ground planes, or other conductive structures in passivation structure 102. The remaining seed 104 can serve (or be referred to) as a barrier partially surrounding conductive structure 106. For example, barrier 104 can be between conductive structure 106 and passivation structure 102. In response to the CMP operation, the upper sides of barrier 104, conductive structure 106, and passivation structure 102 can be coplanar.

FIG. 2D shows a cross-sectional view of electronic device 200 at a later stage of manufacture. In the example shown in FIG. 2D, inorganic barrier 108 can be provided over upper sides of barrier 104, conductive structure 106, and passivation structure 102.

In accordance with various examples, inorganic barrier 108 can comprise an inorganic dielectric material. For example, inorganic barrier 108 can comprise silicon nitride (Si3N4), silicon dioxide (SiO2), silicon oxynitride (SiON), or other inorganic dielectric material. In some examples, inorganic barrier 108 is provided using PECVD. In other examples, inorganic barrier 108 can be provided using PVD, CVD, ALD, LPCVD, or other suitable deposition process.

Inorganic barrier 108 can cover the upper sides of conductive structure 106 and passivation structure 102. Inorganic barrier 108 can extend to or contact the ends of barrier 104 that are disposed between conductive structure 106 and passivation structure 102. The combination of barrier 104 and inorganic barrier 108 can encircle or surround conductive structure 106 to provide a four-sided barrier.

FIG. 2E shows a cross-sectional view of electronic device 200 at a later stage of manufacture. In the example shown in FIG. 2E, photoresist or mask 109 can be provided over the upper side of inorganic barrier 108. Openings 111 can be formed in photoresist 109. The portions of inorganic barrier 108 exposed by openings 111 can be removed using, for example, an etching process. The removal of inorganic barrier 108 in openings 111 exposes portions of conductive structure 106 from inorganic barrier 108. Photoresist 109 can be removed after removing the exposed portions of inorganic barrier 108 from over conductive structure 106.

FIG. 2F shows a cross-sectional view of electronic device 200 at a later stage of manufacture. In the example shown in FIG. 2F, passivation structure 110 is provided over the upper side of inorganic barrier 108 and conductive structure 106. Pattern 113 can be provided in the upper side of passivation structure 110. The elements, features, materials, or manufacturing methods of passivation structure 110 can be similar to or the same as those of passivation structure 102.

Passivation structure 110 can be patterned using, for example, a photo-patterning process that can include a photolithographic mask through which light is exposed to photo-pattern desired features, such as pattern 113, in passivation structure 110. Pattern 103 can be configured to form vias, traces, ground planes, or any other desired conductive structures in passivation structure 110. In some examples, pattern 113 can include vias extending completely through passivation structure 110, such that conductive structure 106 is exposed by the vias in pattern 113. Pattern 113 can also include trace patterns extending partially through passivation structure 110, such that a portion of passivation structure 110 remains between the bottom side of the trace patterns 113 and the upper sides of conductive structure 106, inorganic barrier 108 and/or passivation structure 102.

In accordance with various examples, a seed 114 can be provided over passivation structure 110 and in patterns 113. Seed 114 can extend to the portions of conductive structure 106 exposed by pattern 113. Seed 114 can be provided over the upper side of passivation structure 110 and on the walls defining patterns 113. The elements, features, materials, or manufacturing methods of seed 114 can be similar to seed 104, as previously described. In accordance with various examples, seed 114 can comprise a barrier layer (e.g., a Ti or TiN layer) directly on passivation structure 110 and a plating seed layer (e.g., a Cu seed layer) on the barrier layer.

FIG. 2G shows a cross-sectional view of electronic device 200 at a later stage of manufacture. In the example shown in FIG. 2G, conductive structure 116 can be provided on the upper side of seed 114. The elements, features, materials, or manufacturing methods of conductive structure 116 can be similar to or the same as those of conductive structure 106, as previously described.

In accordance with various examples, conductive structure 116 can be provided to completely cover the upper side of seed 114 and passivation structure 110. In some examples, seed 114 can serve as seed for plating conductive structure 116. The portions of conductive structure 116 located in via patterns in passivation structure 110 can be coupled to the portions of conductive structure 106 exposed from passivation structure 102.

FIG. 2H shows a cross-sectional view of electronic device 200 at a later stage of manufacture. In the example shown in FIG. 2H, a CMP process can be used to remove seed 114 and conductive structure 116 from over the upper-most side of passivation structure 110, leaving conductive structure 116 within patterns 113. Conductive structure 116 can fill or partially fill pattern 113 to provide traces, vias, pads, ground planes, or other conductive structures in passivation structure 110.

FIG. 2I shows a cross-sectional view of electronic device 200 at a later stage of manufacture. In the example shown in FIG. 2I, a portion of conductive structure 116 can be removed from patterns 113, leaving portions 119 of passivation structure 110 protruding above the upper sides of conductive structure 116. In some examples, portions of conductive structure 116 can be removed by etching (e.g., wet etching or dry etching) to leave the upper side of conductive structure 116 recessed from the upper side of passivation structure 110. Seed 114 can also be removed from along the sidewalls of protrusions 119. The upper, exposed ends of seed 114 can be substantially coplanar with the upper side of conductive structure 116. The remaining portion of seed 114 can serve (or be referred to) as a barrier partially surrounding conductive structure 116. For example, barrier 114 can be between conductive structure 116 and passivation structure 110.

FIG. 2J shows a cross-sectional view of electronic device 200 at a later stage of manufacture. In the example shown in FIG. 2J, seed 124 can be provided over passivation structure 110. The elements, features, materials, or manufacturing methods of seed 124 can be similar to or the same as seed 104 and/or seed 114. In accordance with various examples, seed 124 can comprise a barrier layer (e.g., a Ti or TiN layer) directly on passivation structure 110 and a plating seed layer (e.g., a Cu seed layer) on the barrier layer.

FIG. 2K shows a cross-sectional view of electronic device 200 at a later stage of manufacture. In the example shown in FIG. 2K, photoresist or mask 115 can be provided over passivation structure 110, seed 124, and conductive structure 116. Photoresist 115 can extend to portions of conductive structure 116 located between protrusions 119 of passivation structure 110. Photoresist 115 can also extend to portions of conductive structure 116 located in one or more of the via patterns in passivation structure 110. The elements, features, materials, or manufacturing methods of photoresist 115 can be similar to or the same as photoresist 109, described above. Openings 117 can be defined through photoresist 115 to expose portions of seed 124. Openings 117 can be located over protrusions 119 of passivation structure 110 and can expose the portion of barrier 124 on the upper sides of protrusions 119. Photoresist 115 can extend over and along the sidewalls of protrusions 119, such that the seed 124 on the sidewalls of protrusions 119 is covered by photoresist 115. One or more of the openings 117 in photoresist 115 can also be located over portions of conductive structure 116 located in one or more of the via patterns in passivation structure 110.

FIG. 2L shows a cross-sectional view of electronic device 200 at a later stage of manufacture. In the example shown in FIG. 2L, conductive structure 126 can be provided over seed 124 in opening 117 of photoresist 115. The elements, features, materials, or manufacturing methods of conductive structure 126 can be similar to or the same as those of conductive structure 116 or other conductive structures described herein.

FIG. 2M shows a cross-sectional view of electronic device 200 at a later stage of manufacture. In the example shown in FIG. 2M, photoresist 115 and the portions of seed 124 not covered by conductive structure 126 (i.e., the portions exposed from conductive structure 126) can be removed.

In some examples, the portions of conductive structure 126 located on protrusions 119 of passivation structure 110 can form or be referred to as traces of conductive structure 126. In some examples, the portions of conductive structure 126 located on conductive structure 116 can comprise or be referred to as pads and/or vias of conductive structure 126. In accordance with various examples, the traces of conductive structure 126 can interleave laterally with the traces of conductive structure 116. For example, in a plan view a trace of conductive structure 126 can be laterally between adjacent traces of conductive structure 116, and a trace of conductive structure 116 can be laterally between adjacent traces of conductive structure 126.

Seed 124 can remain between conductive structure 126 and the upper side of protrusions 119, and be removed from along the sidewalls of protrusions 119. The lateral exposed ends of seed 124 can be substantially coplanar with the lateral sides of conductive structure 126. The remaining portion of seed 124 can serve (or be referred to) as a barrier located between conductive structure 126 and passivation structure 110.

FIG. 2N shows a cross-sectional view of electronic device 200 at a later stage of manufacture. In the example shown in FIG. 2N, inorganic barrier 112 can be provided over passivation structure 110, conductive structure 116, and conductive structure 126. Inorganic barrier 108 can comprise an inorganic dielectric material, such as for example, Si3N4, SiO2, or SiON. In some examples, inorganic barrier 108 can be provided using PECVD. In accordance with various examples, the elements, features, materials, or manufacturing methods of inorganic barrier 112 can be similar to or the same as those of inorganic barrier 108, as previously described.

In accordance with various examples, inorganic barrier 112 can cover the upper and lateral sides of conductive structure 126. Inorganic barrier 112 can extend to or contact the ends of seed 124 that are disposed between conductive structure 126 and protrusions 119. The combination of barrier 124 and inorganic barrier 112 can encircle or surround conductive structure 126 to provide a four-sided barrier, with inorganic barrier 112 covering and protecting the upper side and lateral sides of conductive structure 126 and barrier 124 covering and protecting the lower side of conductive structure 126.

In various examples, inorganic barrier 112 can also cover the upper side of conductive structure 116. Inorganic barrier 112 can extend to or contact the ends of barrier 114 between conductive structure 116 and passivation structure 110. The combination of barrier 114 and inorganic barrier 112 can encircle or surround conductive structure 116 to provide a four-sided barrier, with inorganic barrier 112 covering and protecting the upper side of conductive structure 116, and barrier 114 covering and protecting the lower side and lateral sides of conductive structure 116. Inorganic barrier 112 located on the lateral sides of protrusions 119 can provide further protection against electron migration from the interleaved traces of conductive structures 106 and 116.

FIG. 2O shows a cross-sectional view of electronic device 200 at a later stage of manufacture. In the example shown in FIG. 2O, photoresist or mask 125 can be provided over inorganic barrier 112. In accordance with various examples, the elements, features, materials, or manufacturing methods of photoresist 125 can be similar to or the same as those of photoresist 109, as previously described.

Photoresist 125 can extend around the lateral sides of protrusions 119. Photoresist 125 can include openings 127 over portions of conductive structure 126 and/or conductive structure 116. Portions of inorganic barrier 112 exposed by openings 127 can be removed to selectively expose conductive structure 116 and conductive structure 126. In accordance with various example, openings 127 can be configured such that removal of inorganic barrier 112 from over vias 128 of conductive structure 116 can also remove inorganic barrier 112 from the sidewalls of passivation structure 110 over vias 128.

FIG. 2P shows a cross-sectional view of electronic device 200 at a later stage of manufacture. In the example shown in FIG. 2P, passivation structure 120 can be provided over passivation structure 110, inorganic barrier 112, conductive structure 106, and conductive structure 126. In accordance with various examples, the elements, features, materials, or manufacturing methods of passivation structure 120 can be similar to or the same as those of passivation structure 102, passivation structure 110 or other passivation structures described herein. Pattern 121 can be provided in passivation structure 120.

Pattern 121 can be configured to form vias, traces, ground planes, or any other desired conductive structures in passivation structure 120. In some examples, pattern 121 can include vias extending completely through passivation structure 120, such that conductive structure 116 and/or conductive structure 126 is/are exposed by the vias in pattern 121. Pattern 121 can also include trace patterns extending partially through passivation structure 120. For example, a portion of passivation structure 120 can remain between the bottom side of the trace patterns 121 and the upper sides of conductive structure 126, inorganic barrier 112, and conductive structure 116.

FIG. 2Q shows a cross-sectional view of electronic device 200 at a later stage of manufacture. In the example shown in FIG. 2Q, seed 134 is provided over passivation structure 120, and conductive structure 136 is provided over seed 134. The elements, features, materials, or manufacturing methods of seed 134 can be similar to those or the same as those of seed 124, 114, and/or 104, as previously described. The elements, features, materials, or manufacturing methods of conductive structure 136 can be similar to or the same as those conductive structure 106, 116, and/or 126, as previously described. Conductive structure 136 can be provided in surplus to cover the exposed side of seed 134 and the upper side of passivation structure 120. In some examples, via 129 of conductive structure 136 can extend to and/or can contact conductive structure 116.

FIG. 2QA shows a detailed view of via 129 and via 128 in region A of FIG. 2Q. As shown in the example of FIG. 2QA, the sidewalls of passivation structure 110 over via 128 can be devoid of inorganic barrier 112 and barrier 114. Passivation structure 120 can be between and/or contacting barrier 134 and passivation structure 110. An upper side 118 of via 128 can also be devoid of inorganic barrier 112. For example, openings 127 of mask 125 in FIG. 2O can be configured to expose the sidewalls of passivation structure 110 over via 128. Passivation structure 120 can contact upper side 118 of via 128 and the ends of barrier 114. Via 129 of conductive structure 136 can be coupled to via 128 of conductive structure 116.

FIG. 2R shows a cross-sectional view of electronic device 200 at a later stage of manufacture. In the example shown in FIG. 2R, CMP can be performed to remove seed 134 and conductive structure 136 from over the upper-most side of passivation structure 120. Conductive structure 136 can fill or partially fill pattern 121 to provide traces, vias, ground planes, pads, or other conductive structures in passivation structure 120.

In some examples, trace portions of conductive structure 136 can interleave laterally with the traces of conductive structure 126. For example, in a plan view a trace of conductive structure 136 can be laterally between adjacent traces of conductive structure 126, and a trace of conductive structure 126 can be laterally between adjacent traces of conductive structure 136. In some examples traces of conductive structure 136 can be vertically aligned (e.g., vertically overlapping) traces of conductive structure 116. Traces of conductive structure 126 and conductive structure 136 can both be located in passivation structure 120. Barrier 134 and inorganic barrier 112 can reduce or prevent electron migration between traces of conductive structures 126 and 136, which can allow for increased trace density and improved electrical performance within electronic device 200.

In some examples, a portion of conductive structure 136 can be removed from patterns 121 in passivation structure 120. Portions (or protrusions) 131 of passivation structure 120 can protrude above the upper sides of conductive structure 136. In some examples, the upper portions of conductive structure 136 can be removed by etching (e.g., wet etching or dry etching) to leave the upper side of conductive structure 136 recessed from the upper side of passivation structure 120. Seed 134 can also be removed from along the sidewalls of protrusions 131. The upper, exposed ends of seed 134 can be substantially coplanar with the upper side of conductive structure 136. The remaining portion of seed 134 can serve (or be referred to) as a barrier partially surrounding conductive structure 136. For example, barrier 134 can be between conductive structure 136 and passivation structure 120.

FIG. 2S shows a cross-sectional view of electronic device 200 at a later stage of manufacture. In the example shown in FIG. 2S, steps similar to those of FIGS. 2J to 2O can be repeated to provide barrier 144, conductive structure 146, and inorganic barrier 122. The upper side of via 129 of conductive structure 136 can be exposed from inorganic barrier 122 by an etching process. In some examples, trace portions of conductive structure 146 (e.g., portions of conductive structure 146 located on protrusions 131 of passivation structure 120) can interleave laterally with the traces of conductive structure 136. For example, in a plan view a trace of conductive structure 146 can be laterally between adjacent traces of conductive structure 136, and a trace of conductive structure 136 can be laterally between adjacent traces of conductive structure 146. In some examples traces of conductive structure 146 can be vertically aligned (e.g., vertically overlapping) traces of conductive structure 126.

In accordance with various examples, the combination of barrier 134 and inorganic barrier 122 can encircle or surround conductive structure 136 to provide a four-sided barrier. For example, inorganic barrier 122 can cover or protect the upper side of conductive structure 136, and barrier 124 can cover or protect the lower side and lateral sides of conductive structure 136.

The combination of barrier 144 and inorganic barrier 122 can encircle or surround conductive structure 146 to provide a four-sided barrier. For example, inorganic barrier 122 can cover or protect the upper side and lateral sides of conductive structure 146, and barrier 144 can cover or protect the lower side of conductive structure 146.

FIG. 2T shows a cross-sectional view of electronic device 200 at a later stage of manufacture. In the example shown in FIG. 2T, passivation structure 130 can be provided over conductive structure 146 and inorganic barrier 122. The elements, features, materials, or manufacturing methods of passivation structure 130 can be similar to or the same as those of passivation structure 120, 110, 102, or other passivation structures described herein. Outward terminals 156 can be coupled to conductive structure 146 and 136. External interconnects 158 can be coupled to outward terminals 156. External interconnects 158 can comprise or be referred to solder balls, bumps, pillars, pads, for example. In some example, outward terminals 156 can comprise or be referred to as under bump metallization. In examples where substrate 101 comprises an electronic component, external interconnects 158 can serve as component interconnects and can be referred to as external input/output terminals of electronic device 200. In examples, where substrate 101 comprises a temporary carrier that is removed from signal distribution structure 100, external interconnects 158 can serve as signal distribution terminals to which an electronic component is coupled.

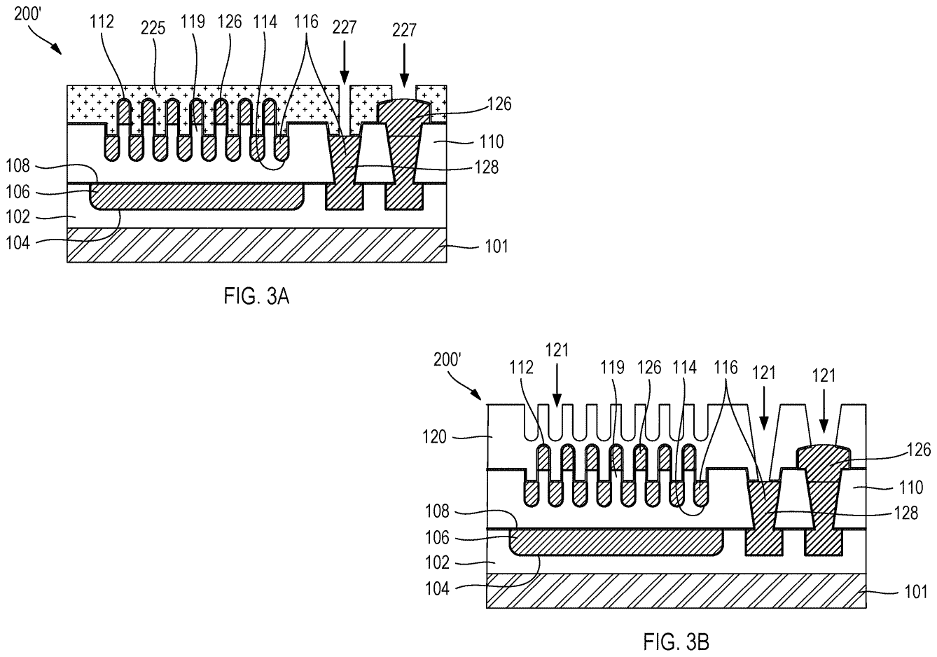

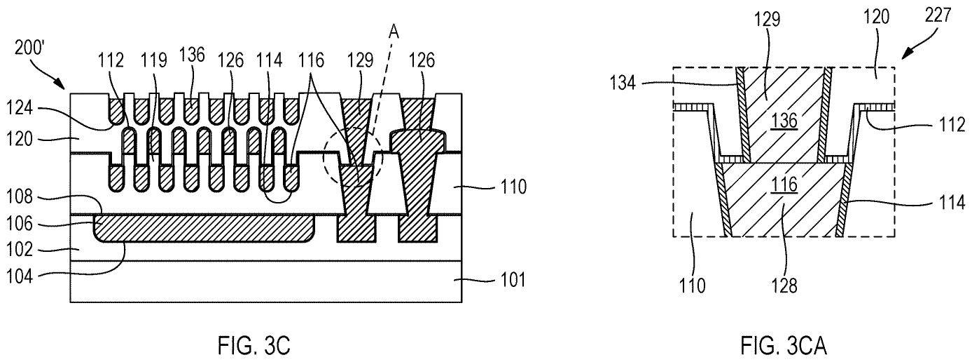

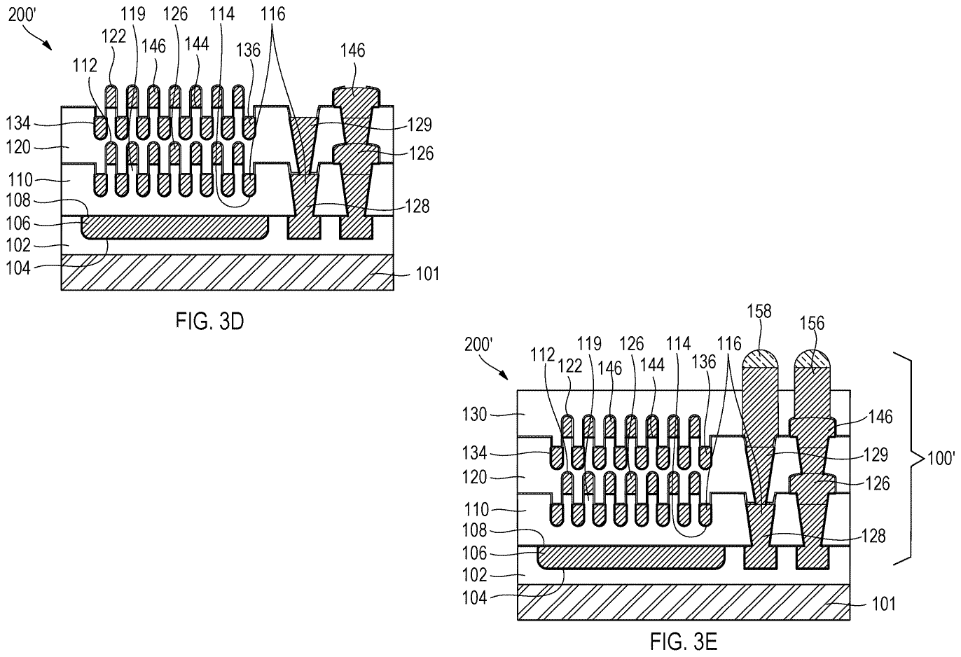

FIGS. 3A-3E show a method of making an example electronic device 200′, in accordance with various examples. The example of FIG. 3A continues from the process step depicted in FIGS. 2A to 2N. In the example of FIG. 3A, photoresist or mask 225 can be provided over inorganic barrier 112, passivation structure 110, and conductive structure 126. In accordance with various examples, the elements, features, materials, or manufacturing methods of photoresist 225 can be similar to or the same as those of photoresist 109, photoresist 125, or other photoresists described herein.

Photoresist 225 can extend around the lateral sides of protrusions 119 and conducive structure 126. Photoresist 225 can include openings 227 over portions of conductive structure 126 and/or conductive structure 116. Portions of inorganic barrier 112 exposed by openings 227 can be removed to selectively expose conductive structure 116 and conductive structure 126. In accordance with various examples, openings 227 can be configured such that removal of inorganic barrier 112 from over vias 128 of conductive structure 116 does not remove inorganic barrier 112 from the sidewalls of passivation structure 110. Electronic device 200 is depicted with open capping, and electronic device 200′ is depicted with inorganic capping, though both capping techniques can be used in various embodiments. Structures and manufacturing techniques of FIGS. 3A to 3E can be similar to those shown and described in FIGS. 2A-2P.

FIG. 3B shows electronic device 200′ at a later stage of manufacture. In the example of FIG. 3B, passivation structure 120 can be provided, as previously described with reference to FIG. 2P. Pattern 121 can be provided in the upper side of passivation structure 120. In accordance with various examples, pattern 121 can expose conductive structure 116 and conductive structure 126. For example, via 128 of conductive structure 116 and a pad portion of conductive structure 126 can be exposed from passivation structure 120.

FIG. 3C shows a cross-sectional view of electronic device 200′ at a later stage of manufacture. In the example shown in FIG. 3C, seed/barrier 124 and conductive structure 136 can be provided, as previously described with reference to FIGS. 2Q and 2R.

FIG. 3CA shows a detailed view of via 129 and via 128 in region A of FIG. 3C. As shown in the example of FIG. 3CA, inorganic barrier 112 can be on the sidewalls of passivation structure 110 over via 128. Inorganic barrier 112 can be between passivation structure 120 and passivation structure 110, such that passivation structure 120 does not contact passivation structure 110. Inorganic barrier 112 can be on upper side 118 of via 128 and the ends of barrier 114, such that inorganic barrier 112 extends from barrier 134 to the sidewall of passivation structure 110. For example, openings 227 of mask 225 in FIG. 3A can be configured to be narrower (e.g., have a smaller diameter or width) than the upper side of via 128. Inorganic barrier 112 can be between passivation structure 120 and upper side 118 of via 128 and the ends of barrier 114.

FIG. 3D shows a cross-sectional view of electronic device 200′ at a later stage of manufacture. In the example shown in FIG. 3D, barrier 144, conductive structure 146, and inorganic barrier 122 can be provided, as previously described with reference to FIG. 2S.

FIG. 3E shows a cross-sectional view of electronic device 200′ at a later stage of manufacture. In the example shown in FIG. 3E, passivation structure 130, outward terminals 156, and external interconnects 158 can be provided, as previously described with reference to FIG. 2T. In accordance with various embodiment, signal distribution structure 100′ of electronic device 200′ can be similar to signal distribution structure 100 of electronic device 200, but with inorganic barrier 112 located along the sidewalls of passivation structure 110 and along the top of via 128, thereby forming a closed, or capped, via 128.

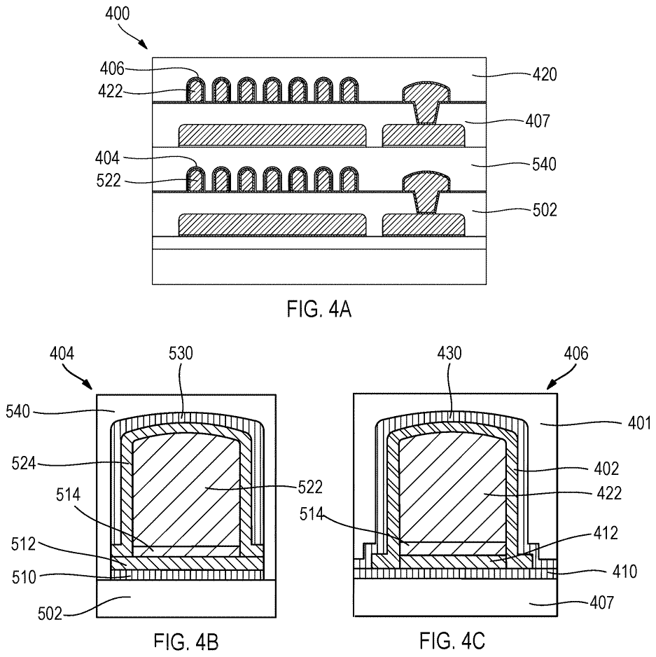

Referring now to FIGS. 4A-4C, an example electronic device 400 is shown, in accordance with various examples. In the example of FIG. 4A, conductive structure 522 can be encircled or surrounded by barrier materials to provide four-sided or all-sided protection.

The detailed views of FIGS. 4B and 4C show example barrier structures formed using an etch process (barrier structure 404) or Ni plating process (barrier structure 406). In the example of FIG. 4B, barrier structure 404 can include metallic barriers 512 and 524 surrounding conductive structure 522. Inorganic barriers 510 and 530 can surround metallic barriers 512 and 524. In some examples, a seed 514 can be between conductive structure 522 and metallic barrier 512. Layers of passivation structures 502, 540, 407, and 420 can be formed in a stack using structures and techniques described elsewhere herein.

In the example of FIG. 4C, barrier structure 406 can include metallic barriers 402 and 412 surrounding conductive structure 422. Inorganic barriers 410 and 430 can surround metallic barriers 402 and 412. In some examples, a seed 414 can be between conductive structure 422 and metallic barrier 412.

In the examples of FIGS. 4B and 4C, the capping structure can project laterally outward from the lower side of example conductive structures 422, 522. Both barrier structures include an inner metallic portion and an outer inorganic portion. The metallic portion of the example capping structures in FIGS. 4B and 4C can protrude by approximately 0.25 micrometers (μm) to approximately 1.5 μm.

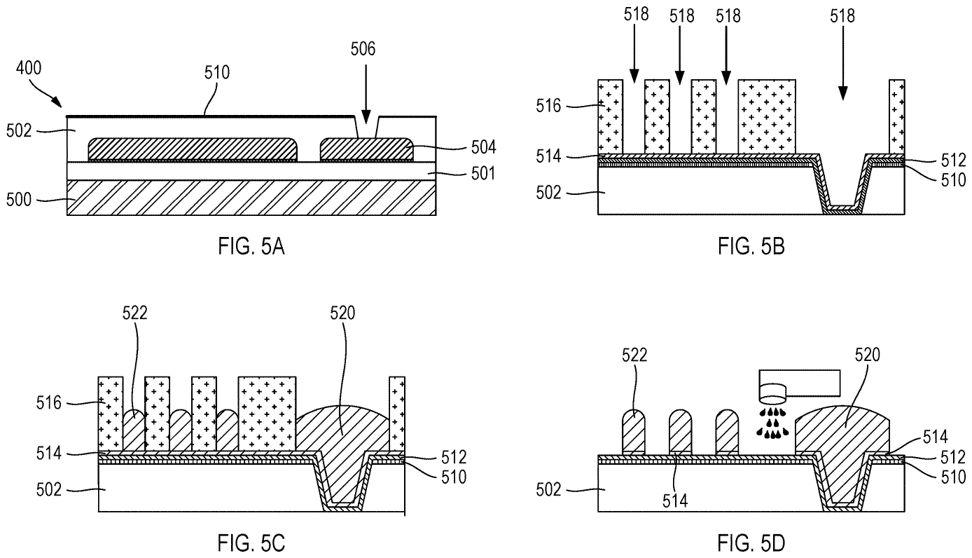

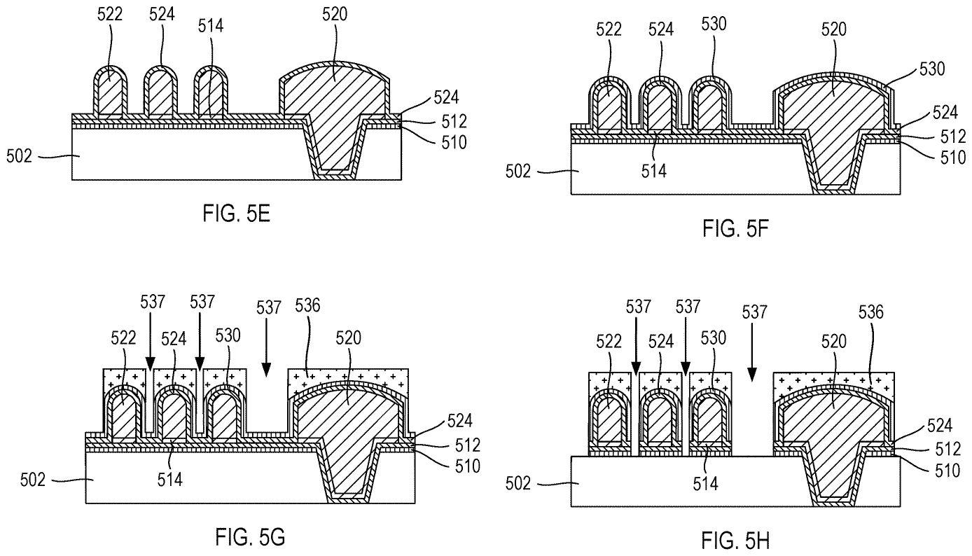

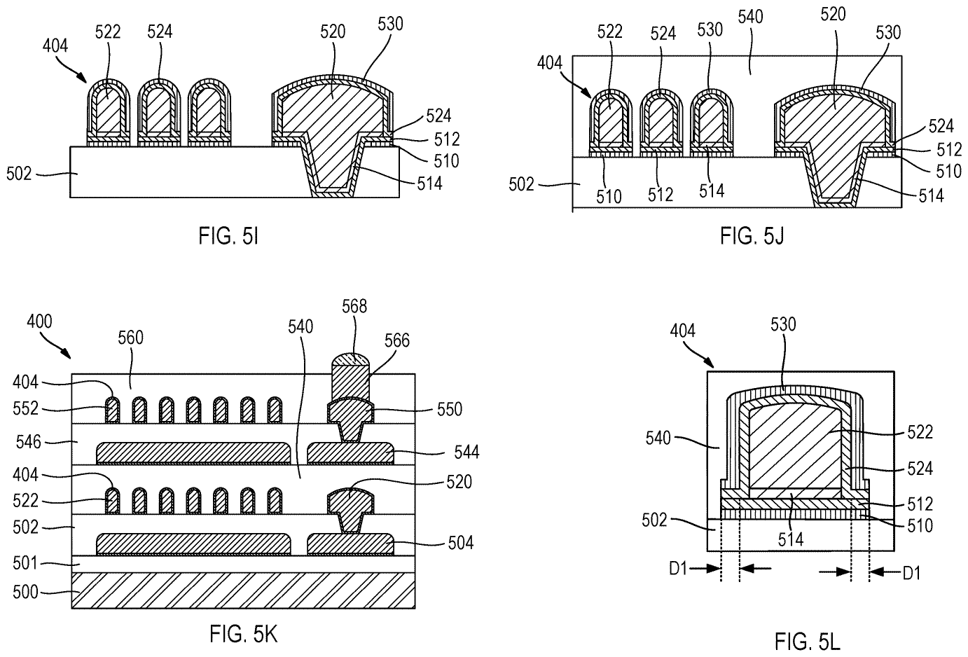

With reference to FIGS. 5A-5M, an example method of making an example electronic device 400 having barrier structure 404 is shown. The various features of FIGS. 5A-5M can comprise structures and manufacturing techniques similar to those shown and described with reference to electronic device 200 in FIGS. 2A-2T.

In the example of FIG. 5A, substrate 500 can be provided with passivation structure 501 disposed over substrate 500. Conductive structure 504 can be provided over passivation structure 501 and substrate 500. Passivation structure 502 can be provided over substrate 500, passivation structure 501, and conductive structure 504. Opening 506 can be defined through passivation structure 502 and can expose a portion of conductive structure 504. Passivation structure 501, passivation structure 502 and conductive structure 504 can comprise structures and manufacturing techniques similar to or the same as those of passivation structures and conductive structures described with reference to electronic device 200. Substrate 500 can be similar to or the same as substrate 101, as previously described.

In accordance with various examples, inorganic barrier 510 can be provided over passivation structure 502. In accordance with various examples, inorganic barrier 510 can comprise an inorganic dielectric material. For example, inorganic barrier 510 can comprise Si3N4, SiO2, SiON, or other inorganic dielectric material. In some examples, inorganic barrier 510 is provided using PECVD. In other examples, inorganic barrier 510 can be provided using PVD, CVD, ALD, LPCVD, or other suitable deposition process.

A portion of inorganic barrier 510 can be removed from over a portion conductive structure 504 exposed by opening 506. For example, inorganic barrier 510 can be removed using a photoresist or mask, in manner similar to inorganic barrier 112 in FIG. 2O or FIG. 3A.

FIG. 5B shows a cross-sectional view of electronic device 400 at a later stage of manufacture. In the example shown in FIG. 5B, barrier 512 and seed 514 can be provided over inorganic barrier 510. In accordance with various examples, barrier 512 can comprise a metallic material. For example, barrier 512 can comprise one or more layers of Ti, TiN, or TiW. Barrier 512 can be formed directly inorganic barrier 510. In some examples, barrier 512 is formed using PVD; however, barrier 512 can be formed via sputtering, electroless plating, CVD, MOCVD, ALD, LPCVD, PECVD, or any other suitable deposition process. In some examples, the thickness of the barrier 512 can be between 15 nanometers (nm) and 100 nm or between 30 nm and 50 nm,

In accordance with various examples, seed 514 can be provided over barrier 512. Seed 514 can comprise a metallic material configured to provide a seed metal for subsequent metal plating. For example, seed 514 can comprise a Cu seed layer. In some examples, the thickness of seed 514 can be between be between 50 nm and 500 nm, or between 100 nm and 300 nm.

In accordance with various examples, photoresist or mask 516 can be provided over the upper side of seed 514. Photoresist 516 can define openings 518. Openings 518 can be configured to provide traces, vias, pads, ground planes, or any other desired conductive structures over and/or in passivation structure 502.

FIG. 5C shows a cross-sectional view of electronic device 400 at a later stage of manufacture. In the example shown in FIG. 5C, conductive structure 520 can be provided in openings 518 of photoresist 516. Conductive structure 520 can be on seed 514. In some example, conductive structure 520 can be formed by plating Cu on seed 514. The elements, features, materials, or manufacturing methods of conductive structure 520 can be similar to or the same as those of conductive structure 126 or other conductive structures described herein. Conductive structure 520 can include traces or conductive structure 522 (e.g., conductive structures 520, 522 can comprise the same conductive material). In some examples, conductive structure 520 can include traces 522 formed using a semi-additive process.

FIG. 5D shows a cross-sectional view of electronic device 400 at a later stage of manufacture. In the example shown in FIG. 5D, photoresist 516 can be removed or stripped away and the portions of seed 514 not covered by conductive structure 520/522 can be removed. In some examples, seed 514 can be removed by etching, for example, a wet etch can be used to remove seed 514 from over barrier 512. In some examples, after removing seed 514, barrier 512 is exposed over barrier 510, outside the footprint of conductive structure 520/522.

FIG. 5E shows a cross-sectional view of electronic device 400 at a later stage of manufacture. In the example shown in FIG. 5E, barrier 524 can be provided over conductive structure 520/522 and barrier 512. Barrier 524 can extend to and contact barrier 512. Barrier 524 can comprise a metallic barrier. For example, barrier 524 can comprise one or more layers of Ti, TiN, TiW, or other metal or metal alloy. In some examples, barrier 524 and barrier 512 can comprise the same material. In some examples, barrier 524 is formed using PVD; however, barrier 524 can be formed by electroless plating, electrolytic plating, sputtering, CVD, MOCVD, ALD, LPCVD, PECVD, or any other suitable metal deposition process.

FIG. 5F shows a cross-sectional view of electronic device 400 at a later stage of manufacture. In the example shown in FIG. 5F, inorganic barrier 530 can be provided. Inorganic barrier 530 can comprise structures and techniques similar to those of other inorganic barriers described herein. For example, inorganic barrier 530 can comprise Si3N4, SiO2, or SiON. In some examples, inorganic barrier 530 is provided using PECVD. In other examples, inorganic barrier 510 can be provided using PVD, CVD, ALD, LPCVD, or other suitable deposition process. In the example of FIG. 5F, inorganic barrier 530 can be provided over the exposed side of barrier 524. In some examples, barrier 524 and barrier 512 can be sandwiched between inorganic barrier 510 and inorganic barrier 530 over passivation structure 502. Barrier 524 can be sandwiched between inorganic barrier 530 and conductive structures 520/522.

FIG. 5G shows a cross-sectional view of electronic device 400 at a later stage of manufacture. In the example shown in FIG. 5G, photoresist or mask 536 can be provided. Photoresist 536 can cover portions of inorganic barrier 530, barrier 524, barrier 512, and inorganic barrier 510 for preservation during an etch process. Photoresist 536 can be provided over upper sides and around lateral sides of conductive structure 520/522 to preserve barrier layers around the conductive structure 520/522 during the etch process. Portions of inorganic barrier 530, barrier 512, barrier 524 or inorganic barrier 510 can be exposed from photoresist 536 through openings 537 for selective removal. Openings 537 in photoresist can be outside the footprint of conductive structures 520/522 and/or outside of the footprint of the portions of inorganic barrier 530 and barrier 524 located on the sidewalls of conductive structures 520/522.

FIG. 5H shows a cross-sectional view of electronic device 400 at a later stage of manufacture. In the example shown in FIG. 5H, portions of inorganic barrier 530, barrier 512, barrier 524, and inorganic barrier 510 can be removed by etching or using other techniques described herein. Passivation structure 502 can provide an etch stop and/or can be exposed after removal of inorganic barrier 530, barrier 512, barrier 524, and inorganic barrier 510. FIG. 5I shows a cross-sectional view of electronic device 400 at a later stage of manufacture. In the example shown in FIG. 5I, photoresist 536 can be stripped or removed, leaving conductive structures 520/522 surrounded by inorganic barrier 530, barrier 512, barrier 524 and inorganic barrier 510. Inorganic barrier 530, barrier 512, barrier 524, and inorganic barrier 510 can form barrier 404 (FIG. 4B) surrounding conductive structure 520/522.

FIG. 5J shows a cross-sectional view of electronic device 400 at a later stage of manufacture. In the example shown in FIG. 5J, passivation structure 540 can be provided over passivation structure 502 and over conductive structure 520/522 with barrier structures 404 provided around conductive structure 520/522. Passivation structure 540 can include one or more layers of photo-definable organic dielectric materials such as, for example, Pl, BCB, or PBO. The elements, features, materials, or manufacturing methods of passivation structure 540 can be similar to or the same as those of passivation structure 102 or other passivation structures described herein.

FIG. 5K shows a cross-sectional view of electronic device 400 at a later stage of manufacture. In the example shown in FIG. 5K, steps of 5A through 5J can be repeated to provide conductive structures 544 and 550/552 having structures and production techniques similar to conductive structures 504 and 520/522, respectively. Similarly, repetition of steps 5A through 5J can provide passivation structures 546 and 560 having structures and production techniques similar to those of passivation structures 502 and 540, respectively. In some examples, barrier structures 404 can be provided surrounding conductive structures (e.g., traces) 552 of conductive structure 550. While FIG. 5K shows conductive structures 504 and 544 as providing ground planes interleaved vertically with conductive structures 520 and 550, it is contemplated and understood that other ordering and layer combinations could be used. In some examples, outward terminals 566 can be coupled to conductive structure 550. External interconnects 568 can be coupled to outward terminals 566. Outward terminals 566 and external interconnects 568 can be similar to or the same as outward terminals 156 and external interconnects 158, respectively, of electronic device 200.

FIG. 5L depicts barrier structure 404 in greater detail. Conductive structure 522 can be completely surrounded or encircled by barrier structure 404. Barrier structure 404 can comprise inorganic barrier 510 along a lower side of conductive structure 522. Barrier 512 can be disposed over inorganic barrier 510. Barrier 524 can be disposed over and around conductive structure 522 and can extend to barrier 512. Inorganic barrier 530 can be disposed over and around barrier 524.

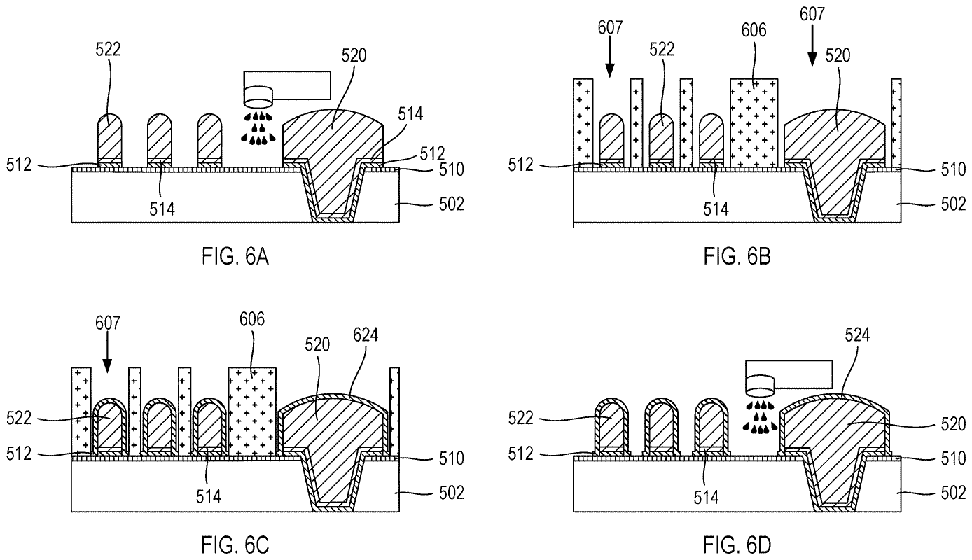

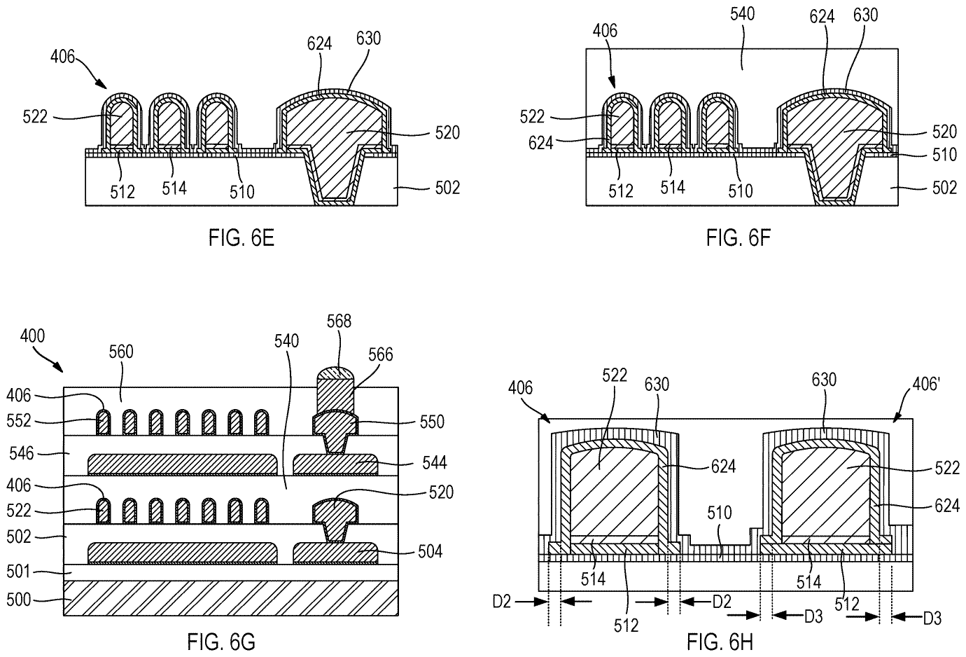

In various examples, a metallic barrier comprising barrier 524 and barrier 512 can surround or encircle conductive structure 522. In some examples, lateral ends of barriers 512 and 524 can be exposed from inorganic barrier 510 and inorganic barrier 530. The ends of barriers 512 and 524 can extend outside a footprint of conductive structure 522, such that the bottom side of barrier 524 can contact a top side of barrier 512. In some examples, barriers 512 and 524 can extend beyond the footprint of conductive structure 522 by distance D1. In some examples, distance D1 can be approximately 0.25 micrometers (μm) to approximately 1.5 μm. While not depicted in the example of FIG. 5L, some examples can include inorganic barrier 530 covering the lateral ends of barriers 512 and 524 in a manner similar to that depicted in FIG. 6H below.

With reference to FIGS. 6A-6H, an example method of making an example electronic device 400 having barrier structure 406 is shown at an early stage of manufacture. The various features techniques of FIGS. 6A-6H can comprise structures and manufacturing techniques similar to those shown and described elsewhere herein. Barrier structure 406 can be formed using structures and techniques similar to those of barrier structure 404, with differences described below and depicted in FIGS. 6A-6H.

FIG. 6A shows a cross-sectional view of electronic device 400 at a later stage of manufacture. The example of FIG. 6A continues from the process step depicted in FIGS. 5A to 5C. In the example of FIG. 6A, photoresist 516 (FIG. 5C) can be removed or stripped, and seed 514 and barrier 512 can be removed by, for example, etching. In some examples, a wet etch can be used to remove portions of seed 514 and barrier 512 exposed from conductive structures 520/522. In some examples, inorganic barrier 510 can be an etch stop and/or can be exposed outside the footprint of conductive structures 520/522, in response to removing seed 514 and barrier 512. In some examples, barrier 512 can remain over inorganic barrier 510, similar to FIG. 5D.

FIG. 6B shows a cross-sectional view of electronic device 400 at a later stage of manufacture. In the example shown in FIG. 6B, photoresist or mask 606 can be provided. Photoresist 606 can cover portions of inorganic barrier 510 between adjacent conductive structures 520/522. Photoresist 606 can include openings 607 over and exposing conductive structure 520/522. Openings 607 in photoresist 606 can expose upper sides and lateral sides of conductive structure 520/522. Photoresist 606 can be spaced apart from the lateral sides of conductive structure 520/522. For example, the width of openings 607 can be greater than the width of conductive structures 520/522, and an upper side of inorganic barrier 510 (or of barrier 512 in examples where it is not etched away) can be exposed from photoresist 606 adjacent conductive structure 520/522. The gap between photoresist 606 and conductive structure 520/522 can enable provision of a metallic barrier (e.g., Ni), as described in further detail below.

FIG. 6C shows a cross-sectional view of electronic device 400 at a later stage of manufacture. In the example shown in FIG. 6C, metallic barrier 624 can be provided over conductive structure 520. Metallic barrier 624 can be provided over traces 522 of conductive structure 520 formed using a SAP, in some examples. Metallic barrier 624 can comprise nickel or nickel alloys in some examples, though other metals can be used in some examples. Barrier 624 can be formed by electroless plating, electrolytic plating, sputtering, PVD, CVD, MOCVD, ALD, LPCVD, PECVD, or any other suitable metal deposition process.

In various examples, barrier 624 can cover the lateral sides and upper side of conductive structures 520/522. Barrier 624 can extend to and contact the upper side of inorganic barrier 510 to completely encircle or surround conductive structure 520/522. The ends of barrier 512 and seed 514 can, in some examples, extend to and contact barrier 624. In examples where barrier 512 remains over inorganic barrier 510, barrier 624 can extend to the upper side of barrier 512, such that a bottom side of barrier 624 contacts an upper side of barrier 512, similar to barrier 524 in FIG. 5E.

FIG. 6D shows a cross-sectional view of electronic device 400 at a later stage of manufacture. In the example shown in FIG. 6D, photoresist 606 can be stripped or removed, thereby exposing the portions of inorganic barrier 510 located outside the footprint of barrier 512. In examples where barrier 512 remains over inorganic barrier 510, barrier 524 and barrier 512 can be removed from between adjacent conductive structures 520/522 to expose inorganic barrier 510.

FIG. 6E shows a cross-sectional view of electronic device 400 at a later stage of manufacture. In the example shown in FIG. 6E, inorganic barrier 630 can be provided over conductive structures 520/522 and inorganic barrier 510. Inorganic barrier 630 can comprise structures and techniques similar to those of other inorganic barriers described herein. For example, inorganic barrier 630 can comprise Si3N4, SiO2, or SiON. In the example of FIG. 6E, inorganic barrier 630 can be provided over the exposed side of barrier 624 and over exposed portions of inorganic barrier 510. Inorganic barrier 630 can extend to and contact inorganic barrier 510.

FIG. 6F shows a cross-sectional view of electronic device 400 at a later stage of manufacture. In the example shown in FIG. 6F, passivation structure 540, as previously described, can be provided over passivation structure 502 and over conductive structure 520/522 with barrier structures 406 provided around conductive structure 520/522.

FIG. 6G shows a cross-sectional view of electronic device 400 at a later stage of manufacture. In the example shown in FIG. 6G, steps of FIG. 5A through FIG. 5C and FIG. 6A through FIG. 6F can be variously repeated to provide conductive structures 544 and 550/552 having structures and production techniques similar to conductive structures 504 and 520/522, respectively. Similarly, repetition of steps FIG. 5A through FIG. 5C and FIG. 6A through FIG. 6F can provide passivation structures 546 and 560 having structures and production techniques similar to those of passivation structures 502 and 540, respectively. In some examples, barrier structures 406 and/or 406′ can be provided surrounding conductive structures (e.g., traces) 552 of conductive structure 550. While FIG. 6G shows conductive structures 504 and 544 as providing ground planes interleaved vertically with conductive structures 520 and 550, it is contemplated and understood that other ordering and layer combinations could be used. In some examples, outward terminals 566 can be coupled to conductive structure 550. External interconnects 568 can be coupled to outward terminals 566. Outward terminals 566 and external interconnects 568 can be similar to or the same as outward terminals 156 and external interconnects 158, respectively, of electronic device 200.

FIG. 6H depicts barrier structure 406 and barrier structure 406′ in greater detail. In accordance with various examples, conductive structure 522 can be completely surrounded or encircled by barrier structure 406. Barrier structure 406 can comprise inorganic barrier 510 along a lower side of conductive structure 522. Barrier 512 can be disposed over inorganic barrier 510, between seed 514 and inorganic barrier 510. A footprint of barrier 512 can match a footprint of conductive structure 522. For example, the ends of barrier 512 can be coplanar with the lateral sides of the conductive structure 522. Barrier 624 can extend to the top side of inorganic barrier 510. A bottom side of barrier 624 can contact a top side of inorganic barrier 510. The ends of barrier 512 can contact barrier 624. Inorganic barrier 630 can be disposed over and around metallic barrier 624. Inorganic barrier 630 can extend to and contact inorganic barrier 510. In some examples, inorganic barrier 630 and/or inorganic barrier 510 can extend continuously between adjacent conductive structures 522.

In various examples, the metallic barrier comprising metallic barrier 624 and barrier 512 can surround or encircle conductive structure 522. In the example of barrier 406, lateral ends of barrier 624 can be covered by inorganic barrier 630 The inorganic barrier comprising inorganic barrier 630 and inorganic barrier 510 can surround or completely encircle the metallic barrier (e.g., metallic barriers 624 and 512) and conductive structure 522. The lateral ends of barrier 624 can extend outside a footprint of conductive structure 522 by distance D2. In some examples, distance D2 can be approximately 0.25 micrometers (μm) to approximately 1.5 μm.

In some examples, conductive structure 522 can be completely surrounded or encircled by barrier structure 406′. Barrier structure 406′ can comprise inorganic barrier 510 along a lower side of conductive structure 522 with barrier 512 disposed over inorganic barrier 510, between seed 514 and inorganic barrier 510. Barrier 512 can extend past the footprint of conductive structure 522. For example, the ends of barrier 512 can be coplanar with ends of barrier 624. Barrier 624 can extend to the top side of barrier 512. A bottom side of barrier 624 can contact a top side of barrier 512. The ends of barrier 512 and the ends of barrier 624 can contact inorganic barrier 630. Inorganic barrier 630 can be disposed over and around metallic barrier 624 and can extend to and contact inorganic barrier 510.

In various examples, the metallic barrier comprising metallic barrier 624 and barrier 512 can surround or encircle conductive structure 522. In the example of barrier 406′, lateral ends of barrier 624 and barrier 512 can be covered by inorganic barrier 630 The inorganic barrier comprising inorganic barrier 630 and inorganic barrier 510 can surround or completely encircle the metallic barrier (e.g., metallic barriers 624 and 512) and conductive structure 522. The lateral ends of barrier 624 and barrier 512 can extend outside a footprint of conductive structure 522 by distance D3. In some examples, distance D3 can be approximately 0.25 micrometers (μm) to approximately 1.5 μm.

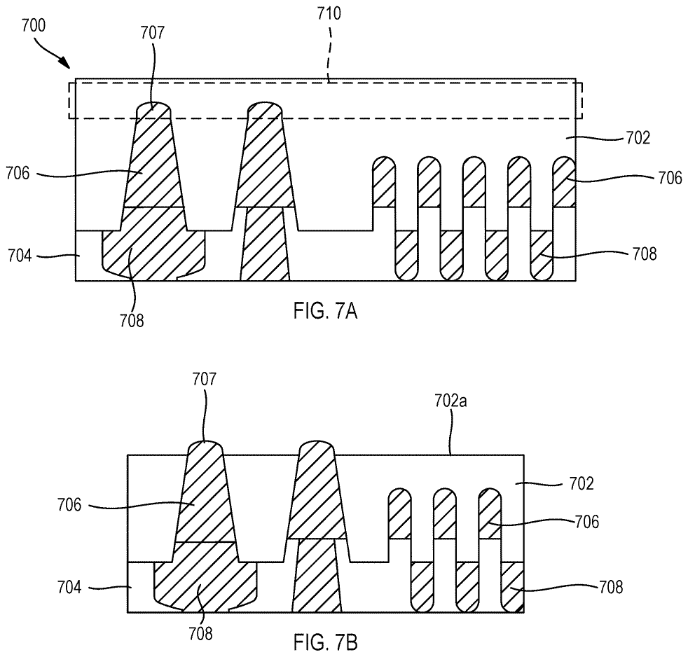

Referring now to FIGS. 7A and 7B, a cross-sectional view of example signal distribution structure 700 for an electronic device is shown, in accordance with various examples. In the example shown in FIGS. 7A and 7B, signal distribution structure 700 comprises passivation structure 702 and passivation structure 704. Conductive structure 706 can be embedded in passivation structure 702. Conductive structure 708 can be provided on passivation structure 702, and passivation structure 704 can be provided over conductive structure 708. Passivation structure 702 can include separation region 710, and tip 707 of conductive structure 706 can extend into separation region 710. Tip 707 can comprise a rounded geometry in some examples. In response to removal of separation region 710, as shown in FIG. 7B, tip 707 can protrude from an exterior side 702a of passivation structure 702.

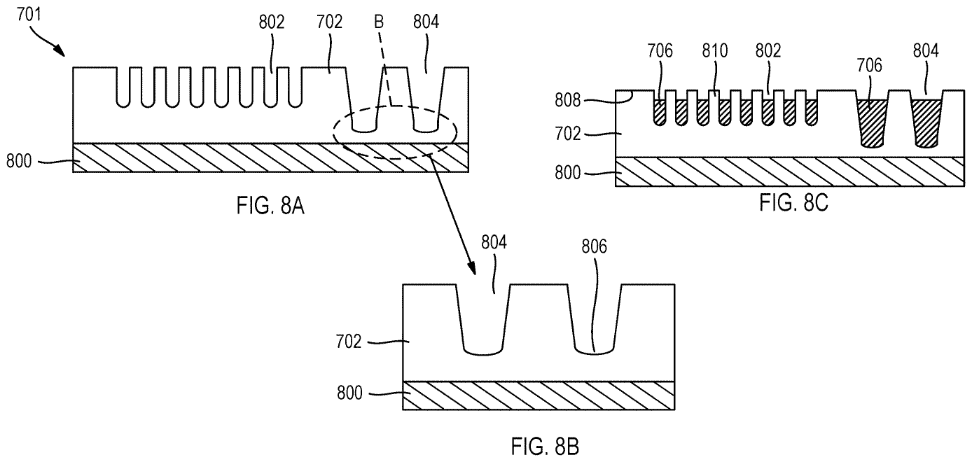

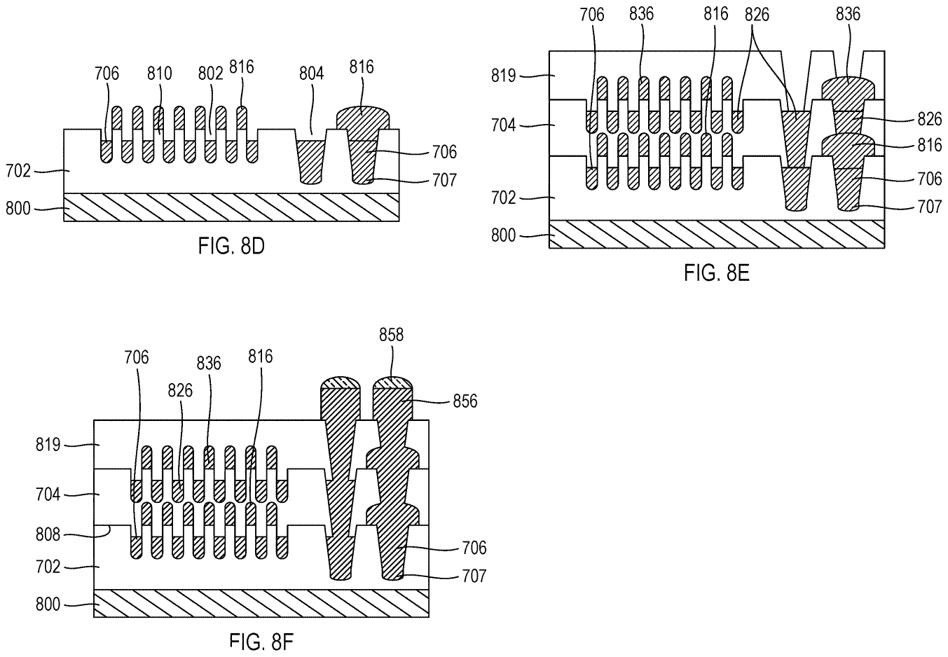

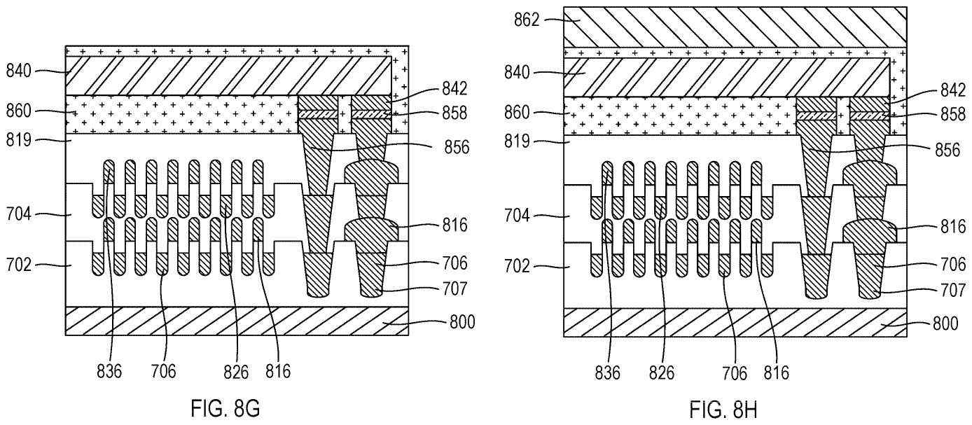

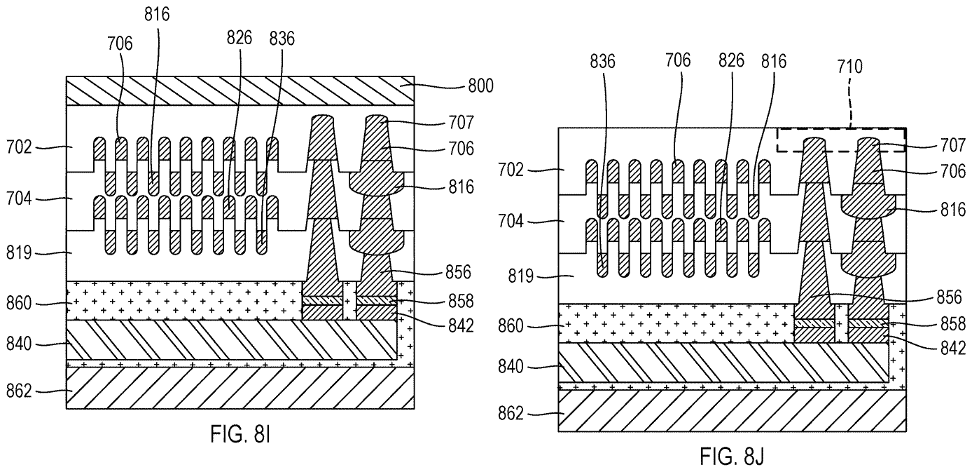

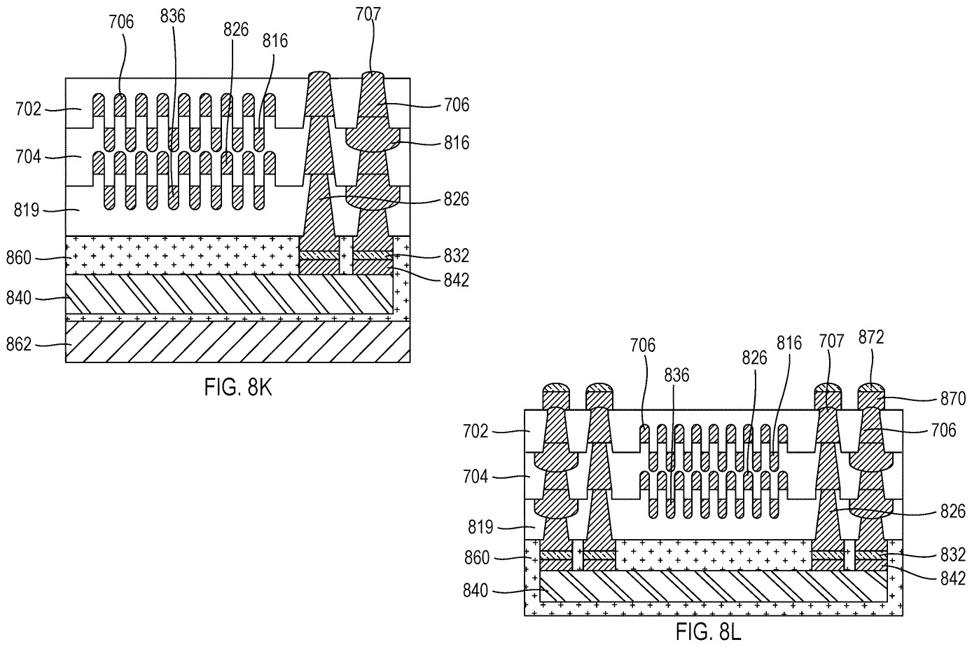

Referring now to FIGS. 8A-8L, an example method of manufacturing an electronic device 701 including signal distribution structure 700 is shown, in accordance with various examples. The various features of FIGS. 8A-8L can comprise structures and manufacturing techniques similar to those shown and described elsewhere herein, for example, elements, features, materials, or manufacturing methods of signal distribution structure 700 can be similar to or the same as those of signal distribution structure 100, as described with reference to FIGS. 1-2T.

FIG. 8A shows a cross-sectional view of electronic device 701 at an early stage of manufacture. In the example of FIG. 8A, passivation structure 702 can be provided over substrate 800. Passivation structure 702 can define trace openings 802 and via openings 804. Trace openings 802 and via openings 804 are used as an example, and other types of conductive structures can be defined in the negative by openings formed in passivation structure 702.

FIG. 8B shows Region B in FIG. 8A in greater detail. As shown in FIG. 8B, via open 804 can be a blind openings, such that a portion of passivation structure 702 remains between tip region 806 of via opening 804 and substrate 800.

Passivation structure 702 can be formed by physical vapor deposition (PVD), chemical vapor deposition (CVD), metal organic chemical vapor deposition (MOCVD), atomic layer deposition (ALD), low pressure chemical vapor deposition (LPCVD), plasma enhanced chemical vapor deposition (PECVD), spin coating, spray coating, dip coating, rod coating, or any other suitable deposition process. Elements, features, materials, or manufacturing methods of passivation structure 702 can be similar to or the same as passivation structure 110.

In various examples, substrate 800 can comprise or be referred to as a wafer, plate, panel, strip, carrier, or temporary carrier. Substrate 800 can comprise semiconductor material (e.g., Si), glass, metal, ceramic, etc. In some examples, a temporary adhesive can be provided on the upper side of substrate 800 to facilitate the separation of passivation structure 702 from substrate 800. The temporary adhesive can be, for example, a heat release tape (or film) or an optical release tape (or film), configured to have its adhesive strength reduced by heat or light, respectively.

With reference to FIG. 8C, electronic device 701 is shown at a later stage of manufacture, in accordance with various examples. In the example of FIG. 8C, conductive structure 706 can be provided in passivation structure 702. Tip 707 of conductive structure 706 can be spaced apart from substrate 800. Conductive structure 706 can be provided in manner similar to conductive structure 116, as shown in FIGS. 2G to 2I. A portion of conductive structure 706 can be removed from openings 802 and 804, leaving protrusions 810 of passivation structure 702 protruding above the upper sides of conductive structure 706. Protrusions 810 can be substantially coplanar with upper side 808 of passivation structure 702. In some examples, portions of conductive structure 706 can be removed by etching (e.g., wet etching or dry etching) to leave the upper side of conductive structure 706 recessed from the upper side of passivation structure 702.

FIG. 8D shows a cross-sectional view of electronic device 701 at a later stage of manufacture. In the example shown in FIG. 8D, conductive structure 816 can be provided over passivation structure 702 and one or more conductive vias of conductive structure 706. Elements, features, materials, or manufacturing methods of conductive structure 816 can be similar to or the same as conductive structure 126. Conductive structure 816 can be provided in manner similar to conductive structure 126, as shown in FIGS. 2J to 2M. The

FIG. 8E shows a cross-sectional view of electronic device 701 at a later stage of manufacture. In the example shown in FIG. 8E, passivation structure 704, conductive structure 826, conductive structure 836, and passivation structure 819 can be provided. Elements, features, materials, or manufacturing methods of passivation structure 704, conductive structure 826, conductive structure 836, and passivation structure 819 can be similar to or the same as passivation structure 120, conductive structure 136, conductive structure 146, and passivation structure 130, respectively. Passivation structure 704, conductive structure 826, conductive structure 836, and passivation structure 819 can in provided in manner similar to passivation structure 120, conductive structure 136, conductive structure 146, and passivation structure 130, as shown in FIGS. 2N to 2T.

FIG. 8F shows a cross-sectional view of electronic device 701 at a later stage of manufacture. In the example of FIG. 8F, outward terminals 856 can be coupled to conductive structure 836 and 826. External interconnects 858 can be coupled to outward terminals 856. External interconnects 858 can comprise or be referred to solder balls, bumps, pillars, pads, for example. Elements, features, materials, or manufacturing methods of outward terminals 856 and external interconnects 858 can be similar to or the same as those of outward terminals 156 and external interconnects 158, as previously described.

FIG. 8G shows a cross-sectional view of electronic device 701 at a later stage of manufacture. In the example of FIG. 8G, electronic component 840 provided over signal distribution structure 700. Electronic component 840 can be coupled to interconnects 832. For example, contacts 842 of electronic component 840 can be coupled to interconnects 832 by reflow, thermocompression bonding, laser assisted bonding, or any other suitable bonding technique. Electronic components 840 can comprise or be referred to as a die, chip, semiconductor package (e.g., multiple interconnected and/or stacked die and/or one or more die coupled to an interposer substrate), passive component, antenna patch, or power device. In some examples, electronic component 840 can comprise a digital signal processor (DSP), network processor, power management unit, audio processor, radio-frequency (RF) circuit, wireless baseband processor, system-on-chip (SoC) processor, memory, sensor, or application-specific integrated circuit (ASIC). In some examples, electronic component 840 can be configured to perform calculation and control processing, store data, or remove noise from electrical signals.

An encapsulant 860 can be provided over electronic component 840 and signal distribution structure 700. In some examples, encapsulant 860 can be provided by compression molding, transfer molding, liquid body molding, vacuum lamination, paste printing, film-assisted molding, or any other suitable deposition process. Encapsulant 860 can comprise or be referred to as a package body, an encapsulating structure, an insulator, a mold, an epoxy molding compound (EMC), a resin, a filler-reinforced polymer, a B-stage compressed film, gel, etc.

FIG. 8H shows a cross-sectional view of electronic device 701 at a later stage of manufacture. In the example of FIG. 8H, carrier 862 can be coupled over electronic component 840 and encapsulant 860. In some examples, a temporary adhesive can be provided between carrier 862 and encapsulant 860 to facilitate the separation carrier 862 from over electronic component 840. The temporary adhesive can be, for example, a heat release tape (or film) or an optical release tape (or film), configured to have its adhesive strength reduced by heat or light, respectively.

FIG. 8I shows a cross-sectional view of electronic device 701 at a later stage of manufacture. In the example of FIG. 8I, signal distribution structure 700 can be rotated 180 degrees, such that substrate 800 is located over signal distribution structure 700 in the orientation of FIG. 8I.

FIG. 8J a cross-sectional view of electronic device 701 at a later stage of manufacture. In the example of FIG. 8J, substrate 800 can be removed to expose passivation structure 702. In some examples, etching can be performed to remove substrate 800. For example, substrate 800 can comprise silicon and a dry etch can be performed to remove substrate 800 from passivation structure 702. In some examples, a substrate 800 can be removed using a laser debonding step. For example, substrate 800 can comprise glass and laser debonding can be used to release substrate 800 from passivation structure 702. As shown in FIG. 8J, a portion of passivation structure 702 (e.g., separation region 710) can remain over tip portion 707 of conductive structure 706 in response to removal of substrate 800.

FIG. 8K shows a cross-sectional view of electronic device 701 at a later stage of manufacture. In the example of FIG. 8K, a portion of passivation structure 702 (e.g., separation region 710 in FIG. 8J) can be removed from over tip portion 707. In some examples, an etching process can be used to remove separation region 710 from passivation structure 702. Tip 707 can protrude above passivation structure 702 in response to removal of separation region 710.

FIG. 8L shows a cross-sectional view of electronic device 701 at a later stage of manufacture. In the example of FIG. 8L, carrier 862 can be removed and outward terminals 870 can be coupled to protruding tips 707 of conductive structure 706. Outward terminals 870 can be coupled through conductive structures 706, 816, 826, 836 to electronic component 840. Outward terminals 870 can comprise external interconnects 872, which can include solder balls, pads, or pillars, for example.

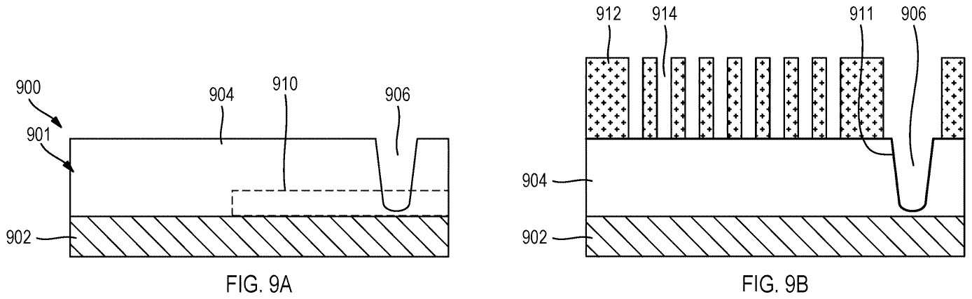

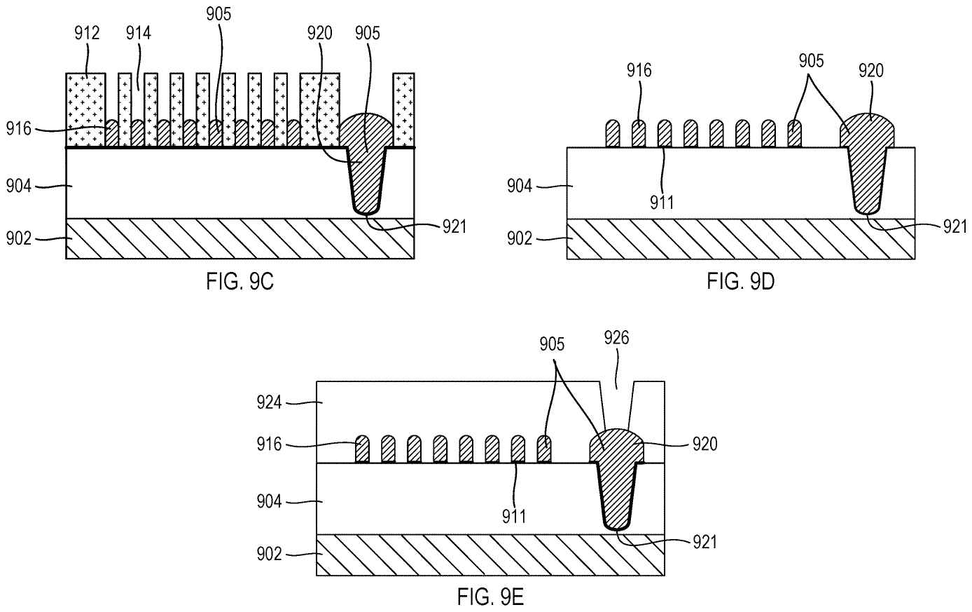

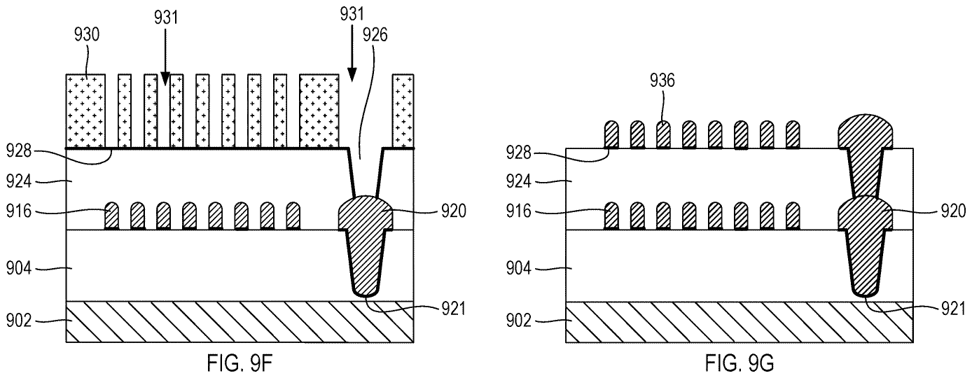

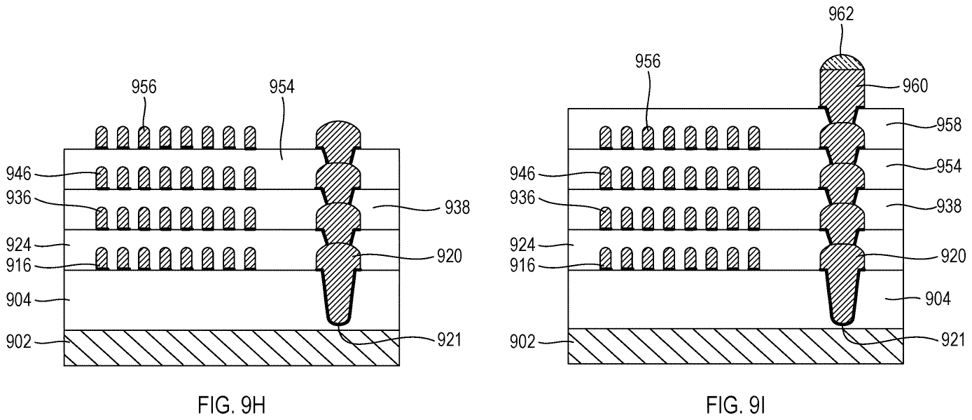

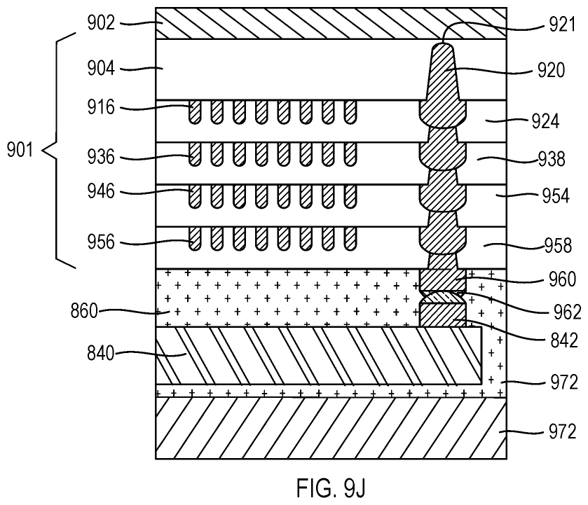

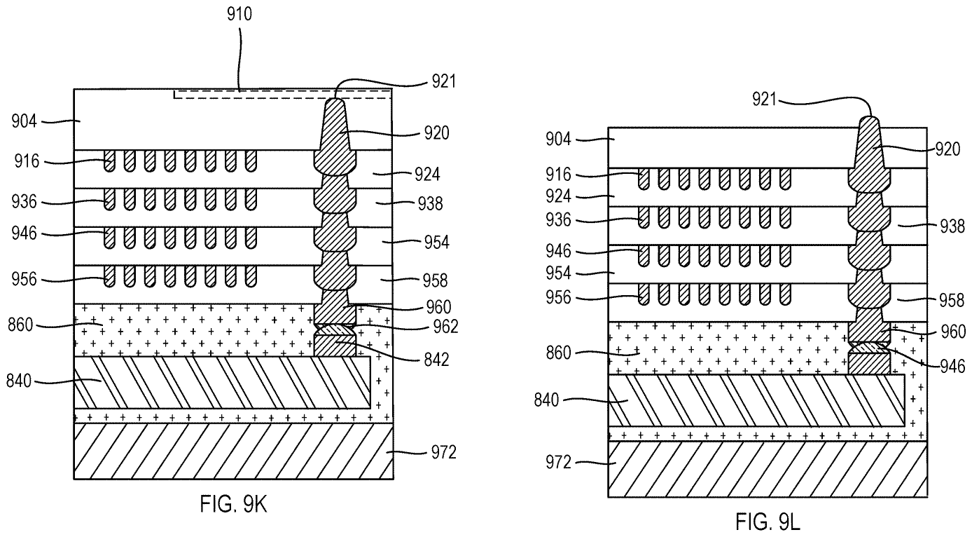

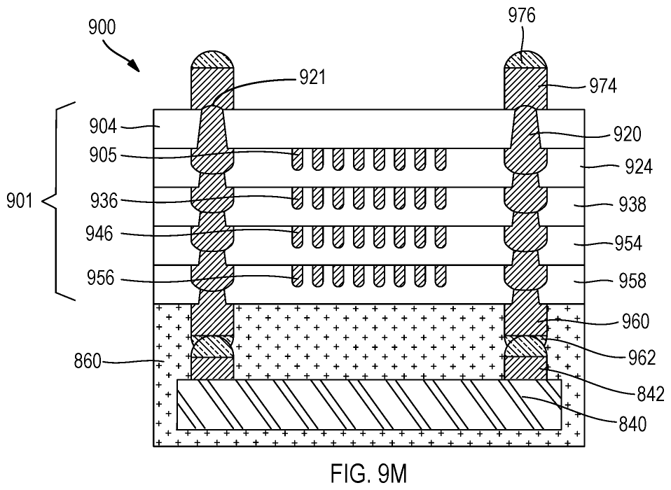

Referring now to FIGS. 9A-9M, an example method of manufacturing electronic device 900 including a signal distribution structure 901 is shown, in accordance with various examples. The various features of FIGS. 9A-9M can comprise structures and manufacturing techniques similar to those shown and described elsewhere herein. For example, electronic device 900 can comprise structures and manufacturing techniques similar to those of electronic device 701 including signal distribution structure 700 (of FIGS. 8A to 8L) or other electronic devices described herein.

FIG. 9A shows a cross-sectional view of electronic device 900 at an early stage of manufacture. In the example of FIG. 9A, passivation structure 904 can be provided over carrier 902. Carrier 902 can be similar to substrate 800, as previously described. Openings 906 can be defined in passivation structure 904. Openings 906 can extend into separation region 910 of passivation structure 904. A portion of passivation structure 904 can remain between the bottom of opening 906 and carrier 902.

FIG. 9B shows a cross-sectional view of electronic device 900 at a later stage of manufacture. In the example of FIG. 9B, seed 911 can be provided over passivation structure 904. Seed 911 can extend into and be coupled to sidewalls defining opening 906. In some examples, seed 911 can include a barrier metal (e.g., Ti, TiN, or TiW) and a plating seed (e.g., Cu) over the barrier metal. Photoresist 912 can be provided over passivation structure 904 and seed 911. Photoresist 912 can define openings 914 over seed 911 and passivation structure 904. Opening 906 in passivation structure 904 can be exposed through photoresist 912.

FIG. 9C shows a cross-sectional view of electronic device 900 at a later stage of manufacture. In the example of FIG. 9C, conductive structure 905 can be provided in openings 914 of photoresist 912. Conductive structure 905 can include traces 916 formed over the upper side of passivation structure 904. In some examples, traces 916 can be made using SAP and can be referred to as SAP traces. Conductive structure 905 can include conductive via 920 in opening 906 of passivation structure 904. Tip 921 of conductive via 920 can be spaced apart from carrier 902. For example, via 920 can be a blind via.

FIG. 9D shows a cross-sectional view of electronic device 900 at a later stage of manufacture. In the example of FIG. 9D, photoresist 912 can be stripped from over passivation structure 904. Traces 916 can remain over the upper side of passivation structure 904. Portions of seed 911 located outside the footprint of conductive structure 905 can be removed.

FIG. 9E shows a cross-sectional view of electronic device 900 at a later stage of manufacture. In the example of FIG. 9E, passivation structure 924 can be provided over passivation structure 904 and conductive structure 905 (e.g., over traces 916 and conductive via 920). Passivation structure 924 can cover traces 916 over the upper side of passivation structure 904. Passivation structure 924 can define opening 926 exposing an upper side of conductive via 920. Elements, features, materials, or manufacturing methods of passivation structure 924 can be similar to or the same as those of passivation structure 120 or other passivation structures described herein.

FIG. 9F shows a cross-sectional view of electronic device 900 at a later stage of manufacture. In the example of FIG. 9F, seed 928 can be provided over passivation structure 924. Seed 928 can extend into and over sidewalls defining opening 926. In some examples, seed 928 can include a barrier (e.g., on or more layers of Ti, TiN, or TiW) and plating seed (e.g., Cu) over the barrier. Photoresist or mask 930 can be provided over seed 928 and passivation structure 924. Openings 931 in photoresist 930 can expose seed 928 and/or conductive via 920. Conductive structure 936 (FIG. 9G) can be provided over passivation structure 924 in openings.

FIG. 9G shows a cross-sectional view of electronic device 900 at a later stage of manufacture. In the example of FIG. 9G, conductive structure 936 is provided over passivation structure 924. Photoresist 930 can be stripped from over passivation structure 924 and the portions of seed 928 outside the footprint of conductive structure 936 can be removed. In accordance with various examples, traces of conductive structure 936 can be referred to as SAP traces.

FIG. 9H shows a cross-sectional view of electronic device 900 at a later stage of manufacture. In the example of FIG. 9H, manufacturing techniques and structures similar to those of FIGS. 9A through 9G can be variously repeated to form passivation structure 938, conductive structure 946, passivation structure 954, and conductive structure 956. The traces of conductive structure 946 and conductive structure 856 can include SAP traces.

FIG. 9I shows a cross-sectional view of electronic device 900 at a later stage of manufacture. In the example of FIG. 9I, passivation structure 958 can be provided over conductive structure 956 and passivation structure 954. Outward terminals 960 and external interconnects 962 can also be provided. External interconnects 962 can comprise or be referred to solder balls, bumps, pillars, pads, for example. Elements, features, materials, or manufacturing methods of outward terminals 960 and external interconnects 962 can be similar to or the same as those of outward terminals 156 and external interconnects 158, as previously described.

FIG. 9J shows a cross-sectional view of electronic device 900 at a later stage of manufacture. In the example of FIG. 9J, electronic component 840, as previously described, can be coupled to signal distribution structure 901. For example, contacts 842 of electronic component 840 can be coupled to external interconnects 962 of signal distribution structure 901. Encapsulant 860, as previously described, can be provided over electronic component 840 and signal distribution structure 901. Carrier 972 can be coupled over electronic component 840 opposite signal distribution structure 901. Signal distribution structure 901 with electronic component 840 coupled thereto can be rotated 180 degrees such that carrier 902 is located over signal distribution structure 901 in the orientation of FIG. 9J. Carrier 972 can be similar to or the same as carrier 862 in FIG. 8H.

FIG. 9K shows a cross-sectional view of electronic device 900 at a later stage of manufacture. In the example of FIG. 9K, carrier 902 can be removed to expose separation portion 910 of passivation structure 904. In some examples, an etch can be performed to remove carrier 902. For example, carrier 902 can comprise silicon and dry etching can be performed to remove carrier 902. In other examples, laser debonding can be performed to remove carrier 902. For example, carrier 902 can be a glass carrier and laser debonding can be used to separate carrier 902 from passivation structure 904. Tip 921 of via 920 remains covered by passivation structure 904 in response to removal of carrier 902.

FIG. 9L shows a cross-sectional view of electronic device 900 at a later stage of manufacture. In the example of FIG. 9L, separation region 910 of passivation structure 904 can be removed. In some examples, an etching process can be used to remove separation portion 910 from passivation structure 904. Tip 921 can protrude from passivation structure 904 in response to removal of separation portion 910.

FIG. 9M shows a cross-sectional view of electronic device 900 at a later stage of manufacture. In the example of FIG. 9M, outward terminals 974 can be coupled to protruding tips 921 of conductive vias 920. Outward terminals 974 can be coupled through conductive structures 905, 936, 946, 956 of signal distribution structure 901 to electronic component 840. Outward terminals 974 can comprise external interconnects 976, which can include solder balls, bumps, pads, or pillars, for example.

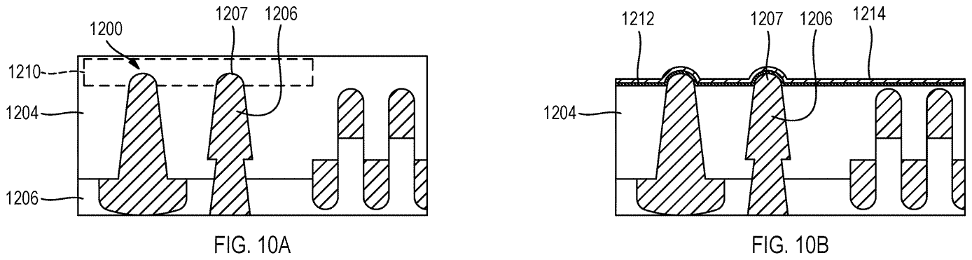

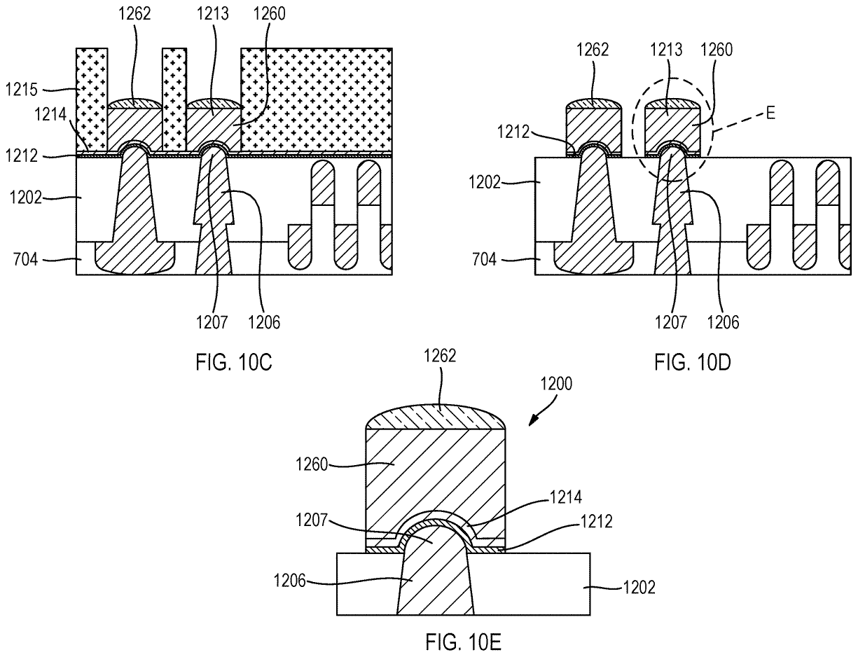

Referring now to FIG. 10A-10E, an example method of manufacturing terminals 1200 is shown, in accordance with various examples. The various features of FIGS. 10A-10E can comprise structures and manufacturing techniques similar to those shown and described elsewhere herein. Terminals 1200 and related electronic devices can comprise structures and manufacturing techniques similar to those described for electronic devices 701 (of FIGS. 7A-8L), 900 (of FIGS. 9A-9M), or other electronic devices described herein. In some examples, terminals 1200 can be incorporated into electronic device 701, electronic device 900, or other electronic devices disclosed herein.

In the example of FIG. 10A a carrier or substrate (e.g., carrier 862 in FIG. 8I or carrier 902 in FIG. 9J) can be removed to expose passivation structure 1204. A separation region or portion 1210 of passivation structure 1204 can be located over tips 1207 of conductive structure 1206. For example, tips 1207 of conductive structure 1206 can be covered by passivation structure 1204. Passivation structure 1204 can be similar to or the same as passivation structure 702 and/or passivation structure 904, as previously described.

FIG. 10B shows a cross-sectional view of terminals 1200 at a later stage of manufacture. In the example of FIG. 10B, separation portion 1210 of passivation structure 1204 can be removed (e.g., by etching, laser ablation, or other suitable removal techniques) to expose tip 1207 of conductive structure 1206. Tip 1207 of conductive structure 1206 can protrude from passivation structure 1204. Barrier 1212 and plating seed 1214 can be provided over passivation structure 1204 and tip 1207 of conductive structure 1206. Barrier 1212 can be between conductive structure 1206 and plating seed 1214. In some examples, barrier 1212 can comprise Ti, TiN, or TiW, and plating seed 1214 can comprise Cu.

FIG. 10C shows a cross-sectional view of terminals 1200 at a later stage of manufacture. In the example of FIG. 10C, photoresist 1215 can be provided over passivation structure 1204. Openings can be provided in photoresist 1215 to expose tips 1207 of conductive structure 1206 (e.g., tips of conductive vias). Conductive structure 1213 can be formed by providing conductive material in openings defined by photoresist 1215. Conductive structure 1213 can include contacts 1260 and external interconnects 1262. In some examples, contacts 1260 can be plated over tips 1207 using plating seed 1214. In some examples, contacts 1260 can include plated Cu.

FIG. 10D shows a cross-sectional view of terminals 1200 at a later stage of manufacture. In the example of FIG. 10D, photoresist 1215 can be removed and the portions of barrier 1212 and seed 1214 located outside the footprint of contact 1260 can be removed. FIG. 10E shows a detailed view of terminals 1200 from region E in FIG. 10D. Seed 1212 between conductive structures 1213 can be removed to electrically isolate individual conductive structures 1213. Tip 1207 can protrude from passivation structure 1204 into an inner side of contact 1260. The inner side of contact 1260 can have a concave geometry along tip 1207. Tip 1207 can have a convex, circular, spherical, or bulbous geometry. The geometry of inner side of contact 1260 can substantially mirror the geometry of tip 1207. Barrier 1212 can remain between tip 1207 and contact 1260. The geometry of barrier 1212 can mirror tip 1207 on a lower or inner side of contact 1260. Tip 1207 protruding from passivation structure 1202 can provide an increased surface area for plating contact 1260, which generates a greater interface area between contact 1260 and conductive structure 1206. The increased interface area can increase the electrical reliability of electronic devices having terminals 1200.

In some examples, electronic devices and related manufacturing techniques can improve size and reliability of electronic devices by including SAP or hybrid SAP and ETR traces. Vias can be revealed by removing a separation layer, and contacts or terminals can be coupled to the vias. The tips of revealed vias can protrude from surrounding passivation structures, and protruding tips can improve adhesion between contacts and the tips of the revealed vias.

In various examples, electronic devices can include barrier structures surrounding or encircling conductive structures. These four-sided or all-sided barrier structures can inhibit oxidation and electron migration, which tends to reduce electronic degradation over time. For example, traces, pads, vias, or other conductive elements can be encircled or surrounded by metallic layers and inorganic layers that form a barrier. The barrier can inhibit or prevent oxidation or moisture penetration that can otherwise break down or damage conductive elements over time. Seed layers and metallic barriers of the present disclosure that form a four-sided metallic barrier can improve electrical performance of conductive elements over time relative to three-sided or other less protective examples of barriers for conductive elements. The added inorganic layer around the metallic barrier can further improve protection of underlying conductive structures.

The present disclosure includes reference to certain examples; however, it will be understood by those skilled in the art that various changes may be made and equivalents may be substituted without departing from the scope of the disclosure. In addition, modifications may be made to the disclosed examples without departing from the scope of the present disclosure. Therefore, it is intended that the present disclosure not be limited to the examples disclosed, but that the disclosure will include all examples falling within the scope of the appended claims.

What is claimed is:

1. An electronic device comprising:
a first passivation structure;
a first inorganic barrier disposed over the first passivation structure;
a first metallic barrier disposed over the first inorganic barrier;
a conductive structure disposed over the first metallic barrier;
a second metallic barrier disposed over the conductive structure; and
a second inorganic barrier disposed over the second metallic barrier.

2. The electronic device of claim 1, wherein a lateral end of the second metallic barrier terminates outside a footprint of the conductive structure by a distance of approximately 0.25 micrometers (μm) to approximately 1.5 μm.

3. The electronic device of claim 2, wherein the first metallic barrier and the second metallic barrier surround the conductive structure.

4. The electronic device of claim 3, wherein the first inorganic barrier and the second inorganic barrier surround the first metallic barrier and the second metallic barrier.

5. The electronic device of claim 1, wherein the second inorganic barrier contacts lateral ends of the second metallic barrier outside a footprint of the conductive structure.

6. The electronic device of claim 5, wherein the conductive structure comprises traces and the second inorganic barrier extending continuously between adjacent traces.

7. The electronic device of claim 1, wherein the first metallic barrier comprises titanium and the second metallic barrier comprises nickel.

8. The electronic device of claim 1, wherein a bottom side of the second metallic barrier contacts a top side of the first metallic barrier.

9. An electronic device, comprising:
a first passivation structure comprising a plurality of protrusions on an upper side of the first passivation structure;
first traces embedded in the first passivation structure and recessed from the protrusions;
second traces disposed on the protrusions;
a second passivation structure disposed over the first passivation structure, the first traces, and the second traces;
a first metallic barrier disposed between the first traces and the first passivation structure;
a second metallic barrier disposed between the second traces and the first passivation structure; and
a first inorganic barrier disposed over an upper side of the first traces, on a sidewall of the protrusions, and between the second traces and the second passivation structure.

10. The electronic device of claim 9, wherein the first metallic barrier comprises titanium and the first inorganic barrier comprises at least one of silicon nitride (Si3N4), silicon dioxide (SiO2), or silicon oxynitride (SiON).

11. The electronic device of claim 9, further comprising:
a conductive via in the first passivation structure; and
the second passivation structure over the first inorganic barrier and the conductive via.

12. The electronic device of claim 11, wherein the second passivation structure contacts a sidewall of the first passivation structure over the conductive via.

13. The electronic device of claim 11, wherein the second passivation structure contacts a top side of the conductive via.

14. The electronic device of claim 11, wherein the first inorganic barrier contacts a top side of the conductive via.

15. The electronic device of claim 9, wherein second traces are laterally interleaved with the first traces.

16. The electronic device of claim 9, further comprising
the second passivation structure over the first inorganic barrier;
third traces disposed in the second passivation structure, wherein the third traces are recessed from an upper side of the second passivation structure;
a third metallic barrier between the third traces and the second passivation structure; and
a second inorganic barrier over the third traces,
wherein the third traces are vertically aligned with the first traces.

17. An electronic device, comprising:
a signal distribution structure comprising a first passivation structure and a conductive structure, the conductive structure including a conductive via extending through the first passivation structure, wherein a tip of the conductive via protrudes from the first passivation structure at a first side of the signal distribution structure;
an electronic component coupled to a second side of signal distribution structure opposite the first side of the signal distribution structure; and
an external interconnect coupled to the tip of the conductive via.

18. The electronic device of claim 17, wherein the conductive structure comprises a plurality of first traces embedded in the first passivation structure.

19. The electronic device of claim 17, wherein the conductive structure comprises a plurality of first traces disposed over the first passivation structure.

20. The electronic device of claim 19, further comprising:
a second passivation structure over the plurality of first traces and the first passivation structure.
